(19) United States
(12) Patent Application Publication
(10) Pub. No.: US 2025/0038108 A1
(43) Pub. Date: Jan. 30, 2025

(54) INTEGRATED CIRCUITS HAVING HIGHLY COMPACT DEVICES THEREIN, AND MEMORY DEVICES USING THE SAME

(71) Applicant: Samsung Electronics Co., Ltd., Suwon-si (KR)

(72) Inventor: Eunsuk HWANG, Suwon-si (KR)

(21) Appl. No.: 18/630,248

(22) Filed: Apr. 9, 2024

(30) Foreign Application Priority Data
Jul. 25, 2023 (KR) 10-2023-0096621

(51) Int. Cl. H01L 23/528; H10B 12/00

(52) U.S. Cl. CPC H01L 23/5283; H10B 12/315; H10B 12/482; H10B 12/485; H10B 12/488

(57) ABSTRACT

A semiconductor device includes a substrate having a pair of second conductive lines thereon, and a first conductive line extending between the pair of second conductive lines and the substrate. A contact plug extends between the pair of second conductive lines and is electrically connected to the first conductive line. A gate electrode extends on the contact plug. First and second semiconductor patterns extend on first and second ones of the pair of second conductive lines, respectively. A gate insulating pattern extends between each of the first and second semiconductive patterns and the gate electrode. The first conductive line may be configured as a word line, and the pair of second conductive lines may be configured as a pair of bit lines. The gate electrode may be configured as a gate electrode of a first access transistor within a first DRAM cell and as a gate electrode of a second access transistor within a second DRAM cell.

### REFERENCE TO PRIORITY APPLICATION

This U.S. non-provisional patent application claims priority under 35 U.S.C. § 119 to Korean Patent Application No. 10-2023-0096621, filed Jul. 25, 2023, the contents of which are hereby incorporated herein by reference.

### BACKGROUND

The present disclosure relates to integrated circuit devices and methods of fabricating the same and, in particular, to semiconductor memory devices including vertical channel transistors and methods of fabricating the same.

A semiconductor device can include an integrated circuit composed of metal-oxide-semiconductor field-effect transistors (MOS-FETs). To meet an increasing demand for semiconductor devices with a small pattern size and a reduced design rule, the MOS-FETs are being aggressively scaled down. The scale down of the MOS-FETs may lead to deterioration in operational properties of the semiconductor device. A variety of studies are conducted to overcome technical limitations associated with the scale-down of the semiconductor device and provide high performance semiconductor device.

### SUMMARY

An embodiment of the inventive concept provides a highly-integrated semiconductor device, which is configured to easily control operations of vertical channel transistors, and methods of fabricating the same.

An embodiment of the inventive concept provides a semiconductor device that includes vertical channel transistors with improved electrical characteristics, and methods of fabricating the same.

According to an embodiment of the inventive concept, a semiconductor device may include a first conductive line on a substrate, which extends in a first direction parallel to a top surface of the substrate, and second conductive lines that extend on the first conductive line, are spaced apart from each other in the first direction, and extend in a second direction, which is parallel to the top surface of the substrate and is non-parallel to the first direction. A contact plug is provided, which is disposed between the second conductive lines and is connected to the first conductive line. A gate electrode extends on the contact plug, and semiconductor patterns are provided on the second conductive lines, respectively. A gate insulating pattern extends between each of the semiconductor patterns and the gate electrode. Conductive patterns are provided on the semiconductor patterns, respectively.

According to another embodiment of the inventive concept, a semiconductor device may include: (i) a first conductive line provided on a substrate and extended in a first direction parallel to a top surface of the substrate, (ii) a lower insulating layer on the first conductive line, (iii) second conductive lines provided on the first conductive line and in the lower insulating layer and spaced apart from each other in the first direction, (iv) a contact plug provided to penetrate the lower insulating layer between the second conductive lines and connected to the first conductive line, (v) a gate electrode on the contact plug, (vi) semiconductor patterns disposed on the second conductive lines, respectively, and spaced apart from each other in the first direction, and (vii) a gate insulating pattern extending between each of the semiconductor patterns and the gate electrode. A bottom surface of the gate insulating pattern may be in contact with a top surface of the lower insulating layer.

According to a further embodiment of the inventive concept, a dual-DRAM cell (i.e., dynamic random access memory cell) is provided, which includes a first access transistor of a first DRAM cell having a cylindrically-shaped gate electrode that extends vertically relative to a surface of an underlying substrate, and a second access transistor of a second DRAM cell that shares the cylindrically-shaped gate electrode. The first access transistor may include a first semiconductor active region that is C-shaped when viewed from a plan layout perspective, and the second access transistor may likewise include a second semiconductor active region that is C-shaped when viewed from the plan layout perspective. The first and second semiconductor active regions may also be configured as mirror images of each other when viewed from the plan layout perspective. A first bit line is provided, which is electrically connected to a source/drain region within the first semiconductor active region, and a second bit line is provided, which is electrically connected to a source/drain region within the second semiconductor active region. The cylindrically-shaped gate electrode may extend between the first and second bit lines. A word line is provided, which extends between the first and second bit lines and the surface of the substrate and is electrically connected to the cylindrically-shaped gate electrode. A first cylindrically-shaped capacitor electrode is provided, and is electrically connected to a source/drain region within the first semiconductor active region. Likewise, a second cylindrically-shaped capacitor electrode is provided, which is electrically connected to a source/drain region within the second semiconductor active region. In some embodiments, a longitudinal axis of the first cylindrically-shaped capacitor electrode, a longitudinal axis of the second cylindrically-shaped capacitor electrode, and a longitudinal axis of the cylindrically-shaped gate electrode extend parallel to each other.

### BRIEF DESCRIPTION OF THE DRAWINGS

FIG. 1 is a plan layout view illustrating a semiconductor device according to an embodiment of the inventive concept.

FIG. 2 is a perspective view schematically illustrating the semiconductor device of FIG. 1.

FIG. 3 is a plan layout view illustrating a semiconductor device according to an embodiment of the inventive concept.

FIG. 4 is a sectional view taken along a line I-I′ of FIG. 3.

FIG. 5 is an enlarged view illustrating a portion ‘P1’ of FIG. 4.

FIGS. 6, 8, 10, 12, 14, and 16 are plan views illustrating a method of fabricating a semiconductor device, according to an embodiment of the inventive concept.

FIGS. 7, 9, 11, 13, 15, and 17 are sectional views taken along lines I-I′ of FIGS. 6, 8, 10, 12, 14, and 16, respectively.

FIG. 18 is a plan view illustrating a semiconductor device according to an embodiment of the inventive concept.

FIG. 19 is a perspective view schematically illustrating a semiconductor device of FIG. 18.

FIG. 20 is a plan view illustrating a semiconductor device according to an embodiment of the inventive concept.

FIG. 21 is a sectional view taken along a line I-I′ of FIG. 20.

FIG. 22 is an enlarged view illustrating a portion ‘P2’ of FIG. 21.

FIGS. 23, 25, and 27 are plan views illustrating a method of fabricating a semiconductor device, according to an embodiment of the inventive concept.

FIGS. 24, 26, and 28 are sectional views taken along lines I-I′ of FIGS. 23, 25, and 27, respectively.

FIG. 29 is a perspective view schematically illustrating a semiconductor device according to an embodiment of the inventive concept.

### DETAILED DESCRIPTION

Example embodiments of the inventive concepts will now be described more fully with reference to the accompanying drawings, in which example embodiments are shown.

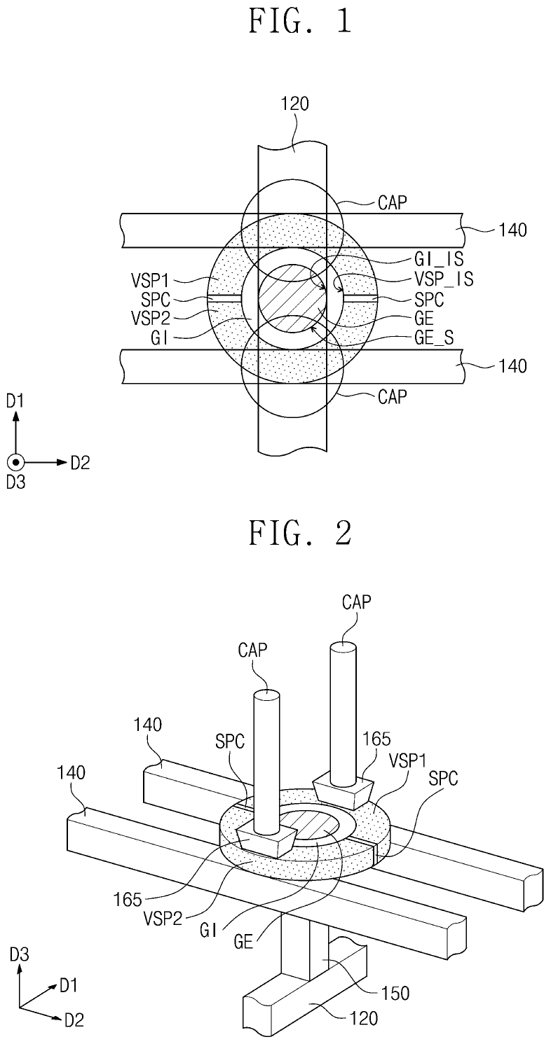

FIG. 1 is a plan view (e.g., from a plan layout perspective) illustrating a semiconductor device according to an embodiment of the inventive concept, and FIG. 2 is a perspective view schematically illustrating a semiconductor device of FIG. 1. Referring to FIGS. 1 and 2, a first conductive line 120 (e.g., word line) may extend in a first direction D1, and second conductive lines 140 (e.g., bit lines) may be disposed on the first conductive line 120. The second conductive lines 140 may be spaced apart from each other in the first direction D1 and may extend in a second direction D2, which is not parallel (e.g., orthogonal) to the first direction D1. The second conductive lines 140 may be disposed to cross the first conductive line 120. A vertical contact plug 150 may be disposed between the second conductive lines 140 and may extend in a third direction D3 that is perpendicular to the first and second directions D1 and D2. The contact plug 150 may be electrically connected to the first conductive line 120.

A gate electrode GE may be disposed on and electrically connected to the contact plug 150. Semiconductor patterns VSP1 and VSP2 may be disposed on the second conductive lines 140, respectively and may be spaced apart from each other in the first direction D1. The semiconductor patterns VSP1 and VSP2 may be electrically connected to the second conductive lines 140, respectively. A gate insulating pattern GI may extend between each of the semiconductor patterns VSP1 and VSP2 and the gate electrode GE.

The gate insulating pattern GI may be a curved or bent pattern, which is extended in a side surface GE_S of the gate electrode GE, when viewed in a plan view. The gate insulating pattern GI may have a ring shape enclosing the side surface GE_S of the gate electrode GE, when viewed in a plan view. An inner side surface GI_IS of the gate insulating pattern GI may be in contact with the side surface GE_S of the gate electrode GE. The inner side surface GI_IS of the gate insulating pattern GI may be a curved or bent surface, which is extended in the side surface GE_S of the gate electrode GE, when viewed in a plan view.

Each of the semiconductor patterns VSP1 and VSP2 may have a curved or bent shape, which is extended in the side surface GE_S of the gate electrode GE, when viewed in a plan view. An inner side surface VSP_IS of each of the semiconductor patterns VSP1 and VSP2 may face the side surface GE_S of the gate electrode GE and may be in contact with the gate insulating pattern GI. The inner side surface VSP_IS of each of the semiconductor patterns VSP1 and VSP2 may be a curved or bent surface, which is extended in the side surface GE_S of the gate electrode GE, when viewed in a plan view.

Separation patterns SPC may extend between the semiconductor patterns VSP1 and VSP2. Between the semiconductor patterns VSP1 and VSP2, the separation patterns SPC may be spaced apart from each other in the second direction D2. The gate electrode GE and the gate insulating pattern GI may extend between the separation patterns SPC. The semiconductor patterns VSP1 and VSP2 and the separation patterns SPC may enclose the gate electrode GE and the gate insulating pattern GI, when viewed in a plan view. The semiconductor patterns VSP1 and VSP2 may be electrically separated from each other by the separation patterns SPC.

Conductive patterns 165 may be disposed on the semiconductor patterns VSP1 and VSP2, respectively, and may be spaced apart from each other in the first direction D1. The conductive patterns 165 may be electrically connected to the semiconductor patterns VSP1 and VSP2, respectively. Capacitors CAP may be disposed on and electrically connected to the conductive patterns 165, respectively.

In an embodiment, the gate electrode GE may be electrically connected to the first conductive line 120 through the contact plug 150, and the first conductive line 120 may serve as a word line. The gate electrode GE, the gate insulating pattern GI, and the semiconductor patterns VSP1 and VSP2 may constitute a pair of vertical channel transistors. The paired vertical channel transistors may share the gate electrode GE and the gate insulating pattern GI and may include the semiconductor patterns VSP1 and VSP2, respectively. Each of the semiconductor patterns VSP1 and VSP2 may be used as a vertical channel of each of the paired vertical channel transistors. The second conductive lines 140 may be electrically connected to the semiconductor patterns VSP1 and VSP2, respectively, and may serve as bit lines. The capacitors CAP may be electrically connected to the semiconductor patterns VSP1 and VSP2, respectively, through the conductive patterns 165. Each of the second conductive lines 140 and each of the capacitors CAP may be electrically connected to source/drain terminals of each of the paired vertical channel transistors. Each of the paired vertical channel transistors and the capacitor CAP connected thereto may constitute a dynamic random access memory (DRAM) cell.

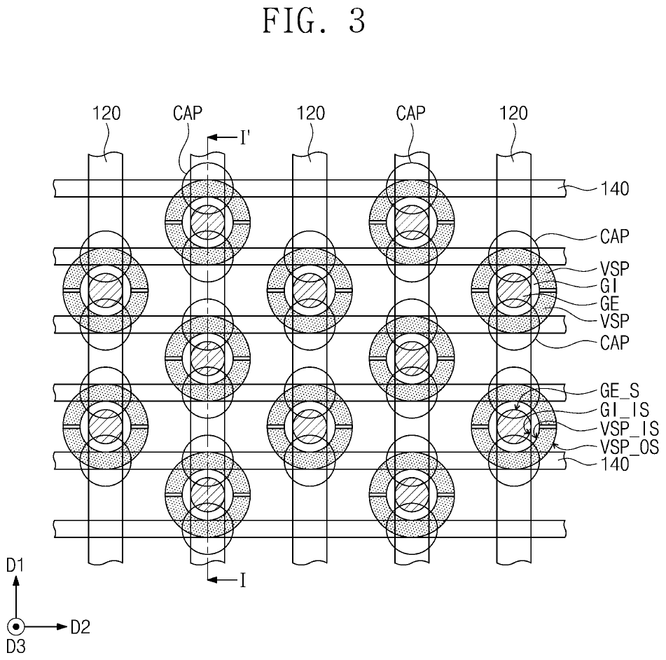

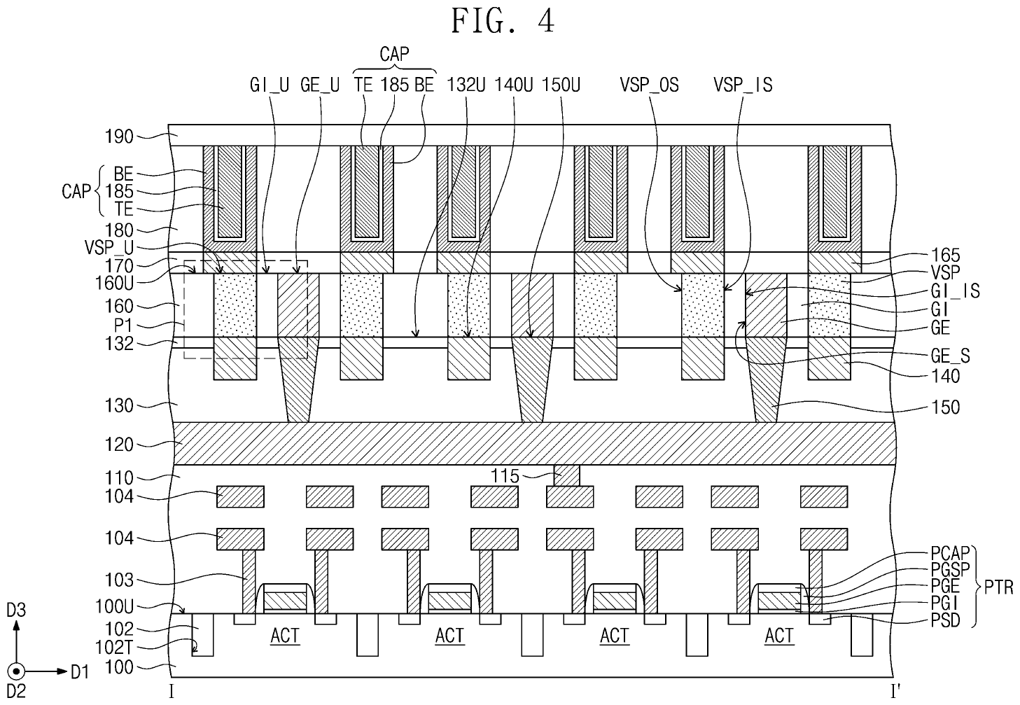

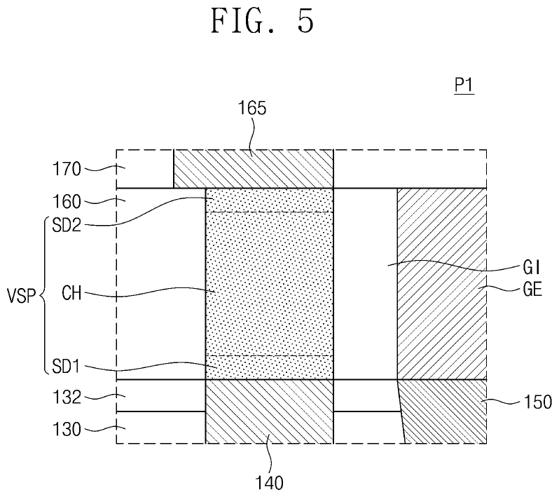

FIG. 3 is a plan layout view illustrating a semiconductor device according to an embodiment of the inventive concept; FIG. 4 is a sectional view taken along a line I-I′ of FIG. 3; and FIG. 5 is an enlarged view illustrating a portion ‘P1’ of FIG. 4. Referring to FIGS. 3 and 4, device isolation patterns 102 may be disposed in a substrate 100 to define active regions ACT in the substrate 100. The substrate 100 may be a semiconductor substrate (e.g., a silicon (Si) substrate, a germanium (Ge) substrate, a silicon-germanium (Si—Ge) substrate, or a semiconductor-on-insulator (SOI) substrate). The device isolation patterns 102 may be formed of or include at least one of silicon oxide, silicon nitride, and/or silicon oxynitride.

Peripheral transistors PTR may be disposed on the active regions ACT of the substrate 100. Each of the peripheral transistors PTR may include a peripheral gate electrode PGE on a corresponding one of the active regions ACT, a peripheral gate insulating pattern PGI between the corresponding active region ACT and the peripheral gate electrode PGE, a peripheral capping pattern PCAP on the peripheral gate electrode PGE, peripheral gate spacers PGSP on side surfaces of the peripheral gate electrode PGE, and peripheral source/drain regions PSD formed in portions of the corresponding active region ACT at both sides of the peripheral gate electrode PGE. The peripheral gate electrode PGE may be formed of or include at least one of doped semiconductor materials, conductive metal nitride materials, and/or metallic materials. The peripheral gate insulating pattern PGI may be formed of or include at least one of silicon oxide, silicon nitride, silicon oxynitride, or high-k dielectric materials. The high-k dielectric materials may include materials (e.g., hafnium oxide (HfO), aluminum oxide (AlO), or tantalum oxide (TaO)) having higher dielectric constants than silicon oxide. The peripheral capping pattern PCAP and the peripheral gate spacers PGSP may include at least one of a silicon oxide layer, a silicon nitride layer, and a silicon oxynitride layer. The peripheral transistors PTR may constitute a peripheral circuit, which is used to operate the DRAM cell according to an embodiment of the inventive concept.

Peripheral contacts 103 and peripheral interconnection lines 104 may be disposed on the substrate 100. The peripheral contacts 103 may be electrically connected to the peripheral source/drain regions PSD of the peripheral transistors PTR, and the peripheral interconnection lines 104 may be electrically connected to the peripheral contacts 103. The peripheral contacts 103 and the peripheral interconnection lines 104 may be formed of or include at least one of conductive materials (e.g., metallic materials). A peripheral insulating layer 110 may be disposed on the substrate 100 to cover the peripheral transistors PTR, the peripheral contacts 103, and the peripheral interconnection lines 104. The peripheral insulating layer 110 may be formed of or include at least one of, for example, silicon oxide, silicon nitride, and/or silicon oxynitride.

First conductive lines 120 may be disposed on the peripheral insulating layer 110 and may extend in a first direction D1 parallel to a top surface 100U of the substrate 100. The first conductive lines 120 may be spaced apart from each other in a second direction D2 that is parallel to the top surface 100U of the substrate 100 and is not parallel to the first direction D1. Each of the first conductive lines 120 may be electrically connected to a corresponding one of the peripheral interconnection lines 104 through a lower contact 115. The first conductive lines 120 and the lower contact 115 may be formed of or include at least one of conductive materials (e.g., metallic materials).

A first lower insulating layer 130 may be disposed on the peripheral insulating layer 110 to cover the first conductive lines 120. The first lower insulating layer 130 may be formed of or include at least one of, for example, silicon oxide, silicon nitride, and/or silicon oxynitride. A second lower insulating layer 132 may be disposed on the first lower insulating layer 130. The second lower insulating layer 132 may be formed of or include a material different from the first lower insulating layer 130. As an example, the second lower insulating layer 132 may include silicon nitride. The first lower insulating layer 130 and the second lower insulating layer 132 may be referred to as a lower insulating layer 130/132.

Second conductive lines 140 may be disposed in the lower insulating layer 130/132 and on the first conductive lines 120. The second conductive lines 140 may be vertically spaced apart from the first conductive lines 120 in a third direction D3, which is perpendicular to the top surface 100U of the substrate 100. The second conductive lines 140 may extend in the second direction D2 and may be spaced apart from each other in the first direction D1. The second conductive lines 140 may be provided to cross the first conductive lines 120. Each of the second conductive lines 140 may be provided to penetrate an upper portion of the lower insulating layer 130/132. As an example, each of the second conductive lines 140 may be provided to penetrate the second lower insulating layer 132 and may extend into the upper portion of the first lower insulating layer 130. Top surfaces 140U of the second conductive lines 140 may be coplanar with a top surface 132U of the lower insulating layer 130/132. The top surfaces 140U of the second conductive lines 140 and the top surface 132U of the lower insulating layer 130/132 may be located at the same height from the substrate 100. In the present specification, the term ‘height’ will be used to represent a vertical length measured from the top surface 100U of the substrate 100 in the third direction D3. The top surface 132U of the lower insulating layer 130/132 may correspond to the top surface 132U of the second lower insulating layer 132. The second conductive lines 140 may be formed of or include at least one of conductive materials (e.g., metallic materials).

Contact plugs 150 may be disposed in the lower insulating layer 130/132 between the second conductive lines 140. In the lower insulating layer 130/132, the contact plugs 150 may be spaced apart from each other in the first and second directions D1 and D2. Each of the contact plugs 150 may be positioned between a pair of second conductive lines 140, which are selected from the second conductive lines 140 to be the closest to each other in the first direction D1. Between the paired second conductive lines 140, each of the contact plugs 150 may be provided to penetrate the lower insulating layer 130/132 and may be electrically connected to a corresponding one of the first conductive lines 120. Ones of the contact plugs 150, which are spaced apart from each other in the first direction D1, may be commonly electrically connected to one of the first conductive lines 120 and may be respectively disposed between the second conductive lines 140. Ones of the contact plugs 150, which are spaced apart from each other in the second direction D2, may be electrically connected to different ones of the first conductive lines 120, respectively, and may be disposed between a pair of second conductive lines 140, which are selected from the second conductive lines 140. Top surfaces 150U of the contact plugs 150 may be coplanar with the top surface 132U of the lower insulating layer 130/132. The top surfaces 150U of the contact plugs 150 and the top surface 132U of the lower insulating layer 130/132 may be located at the same height from the substrate 100. The top surfaces 150U of the contact plugs 150, the top surfaces 140U of the second conductive lines 140, and the top surface 132U of the lower insulating layer 130/132 may be coplanar with each other and may be located at the same height from the substrate 100. The contact plugs 150 may be formed of or include at least one of conductive materials (e.g., metallic materials).

Gate electrodes GE may be disposed on the contact plugs 150, respectively, and electrically connected to the contact plugs 150, respectively. Bottom surfaces of the gate electrodes GE may be in contact with the top surfaces 150U of the contact plugs 150, respectively. The gate electrodes GE may be spaced apart from each other in the first and second directions D1 and D2. Ones of the gate electrodes GE, which are spaced apart from each other in the first direction D1, may be commonly electrically connected to one of the first conductive lines 120 through corresponding contact plugs 150. Ones of the gate electrodes GE, which are spaced apart from each other in the second direction D2, may be respectively electrically connected to different ones of the first conductive lines 120 through corresponding contact plugs 150.

The gate electrodes GE may include at least one of doped polysilicon, metallic materials, conductive metal nitride materials, conductive metal silicide materials, conductive metal oxide materials, or combinations thereof. For example, the gate electrodes GE may be formed of or include at least one of doped polysilicon, Al, Cu, Ti, Ta, Ru, W, Mo, Pt, Ni, Co, TiN, TaN, WN, NbN, TiAl, TIAlN, TiSi, TiSiN, TaSi, TaSiN, RuTiN, NiSi, CoSi, IrOx, RuOx, or combinations thereof. In an embodiment, the gate electrodes GE may include a two-dimensional semiconductor material, and here, the two-dimensional semiconductor material may include graphene, carbon nanotube, or combinations thereof.

Semiconductor patterns VSP may be disposed at both sides of each of the gate electrodes GE. The semiconductor patterns VSP may be spaced apart from each other in the first direction D1 with each of the gate electrodes GE extending therebetween. The semiconductor patterns VSP may be respectively disposed on a pair of second conductive lines 140, which are selected from the second conductive lines 140 to be the closest to each other in the first direction D1, and may be electrically connected to the paired second conductive lines 140, respectively. Bottom surfaces of the semiconductor patterns VSP may be in contact with top surfaces 140U of the paired second conductive lines 140, respectively.

The semiconductor patterns VSP may include at least one of oxide semiconductor materials. For example, the semiconductor patterns VSP may be formed of or include at least one of InxGayZnzO, InxGaySizO, InxSnyZnzO, InxZnyO, ZnxO, ZnxSnyO, ZnxOyN, ZrxZnySnzO, SnxO, HfxInyZnzO, GaxZnySnzO, AlxZnySnzO, YbxGayZnzO, InxGayO, or combinations thereof. In an embodiment, the semiconductor patterns VSP may be formed of or include indium gallium zinc oxide (IGZO). The semiconductor patterns VSP may have a single- or multi-layered structure including an oxide semiconductor material and may be formed of or include at least one of amorphous, crystalline, or polycrystalline oxide semiconductor materials. The semiconductor patterns VSP may have a band gap energy that is greater than that of silicon. For example, the semiconductor patterns VSP may have a band gap energy of about 1.5 eV to 5.6 eV or may have a band gap energy of about 2.0 eV to 4.0 eV.

A gate insulating pattern GI may extend between each of the gate electrodes GE and each of the semiconductor patterns VSP. A bottom surface of the gate insulating pattern GI may be in contact with the top surface 132U of the lower insulating layer 130/132. The semiconductor patterns VSP may be spaced apart from each of the gate electrodes GE with the gate insulating pattern GI extending therebetween. The gate insulating pattern GI may be formed of or include at least one of silicon oxide, silicon oxynitride, high-k dielectric materials, which have dielectric constants higher than that of silicon oxide, or combinations thereof. The high-k dielectric materials may include metal oxide materials or metal oxynitride materials. For example, the high-k dielectric materials may include HfO₂, HfSiO, HfSiON, HfTaO, HfTIO, HfZrO, ZrO₂, Al₂O₃, or combinations thereof.

The gate insulating pattern GI may be a curved or bent pattern that is extended along the side surface GE_S of each of the gate electrodes GE in a direction parallel to the top surface 100U of the substrate 100. For example, the gate insulating pattern GI may be a ring-shaped pattern that is provided to enclose the side surface GE_S of each of the gate electrodes GE in the direction parallel to the top surface 100U of the substrate 100. An inner side surface GI_IS of the gate insulating pattern GI may be in contact with the side surface GE_S of each of the gate electrodes GE. The inner side surface GI_IS of the gate insulating pattern GI may be a curved or bent surface that is extended along the side surface GE_S of each of the gate electrodes GE in the direction parallel to the top surface 100U of the substrate 100.

Each of the semiconductor patterns VSP may be a curved or bent pattern that is extended along the side surface GE_S of each of the gate electrodes GE in the direction parallel to the top surface 100U of the substrate 100. The inner side surface VSP_IS of each of the semiconductor patterns VSP may face the side surface GE_S of each of the gate electrodes GE and may be in contact with the gate insulating pattern GI. The inner side surface VSP_IS of each of the semiconductor patterns VSP may be a curved or bent surface that is extended along the side surface GE_S of each of the gate electrodes GE in the direction parallel to the top surface 100U of the substrate 100.

Separation patterns SPC may extend between the semiconductor patterns VSP. The separation patterns SPC between the semiconductor patterns VSP may be spaced apart from each other in the second direction D2. Each of the gate electrodes GE and the gate insulating pattern GI may extend between the separation patterns SPC. The semiconductor patterns VSP and the separation patterns SPC may enclose each of the gate electrodes GE and the gate insulating pattern GI in the direction parallel to the top surface 100U of the substrate 100. The semiconductor patterns VSP may be electrically separated from each other by the separation patterns SPC. The separation patterns SPC may be formed of or include at least one of, for example, silicon oxide, silicon nitride, and/or silicon oxynitride.

Each of the gate electrodes GE, the gate insulating pattern GI, and the semiconductor patterns VSP may form a pair of vertical channel transistors. Each of the semiconductor patterns VSP may serve as a vertical channel of each of the paired vertical channel transistors. The paired vertical channel transistors may share each of the gate electrodes GE.

A gap-fill insulating layer 160 may be disposed on the second lower insulating layer 132 and may fill a space between the paired vertical channel transistors and another pair of vertical channel transistors adjacent thereto. Each of the semiconductor patterns VSP may have an outer side surface VSP_OS that is opposite to the inner side surface VSP_IS of each of the semiconductor patterns VSP, and the gap-fill insulating layer 160 may cover the outer side surface VSP_OS of each of the semiconductor patterns VSP. The gap-fill insulating layer 160 may fill a space between the outer side surfaces VSP_OS of the semiconductor patterns VSP. Top surfaces VSP_U of the semiconductor patterns VSP, a top surface GI_U of the gate insulating pattern GI, and a top surface GE_U of each of the gate electrodes GE may be coplanar with a top surface 160U of the gap-fill insulating layer 160. The top surfaces VSP_U of the semiconductor patterns VSP, the top surface GI_U of the gate insulating pattern GI, the top surface GE_U of each of the gate electrodes GE, and the top surface 160U of the gap-fill insulating layer 160 may be located at the same height from the substrate 100. The gap-fill insulating layer 160 may be formed of or include at least one of, for example, silicon oxide, silicon nitride, and/or silicon oxynitride.

Conductive patterns 165 may be disposed on and electrically connected to the semiconductor patterns VSP, respectively. Bottom surfaces of the conductive patterns 165 may be in contact with the top surfaces VSP_U of the semiconductor patterns VSP, respectively.

Referring to FIGS. 4 and 5, each of the semiconductor patterns VSP may include a first source/drain region SD1, which is adjacent to each of the second conductive lines 140, a second source/drain region SD2, which is adjacent to each of the conductive patterns 165, and a channel region CH between the first and second source/drain regions SD1 and SD2. The first and second source/drain regions SD1 and SD2 may be spaced apart from each other in the third direction D3, and the channel region CH may be a vertical channel region, which is extended in the third direction D3. Each of the gate electrodes GE, the gate insulating pattern GI, and each of the semiconductor patterns VSP may constitute a vertical channel transistor, and each of the semiconductor patterns VSP may serve as a vertical channel region of the vertical channel transistor.

Referring back to FIGS. 3 and 4, a first upper insulating layer 170 may be disposed on the gap-fill insulating layer 160 to fill a space between the conductive patterns 165. The first upper insulating layer 170 may cover the top surface GI_U of the gate insulating pattern GI, the top surface GE_U of each of the gate electrodes GE, and the top surface 160U of the gap-fill insulating layer 160. The first upper insulating layer 170 may be formed of or include at least one of, for example, silicon oxide, silicon nitride, and/or silicon oxynitride.

In an embodiment, capacitors CAP may be disposed on the conductive patterns 165, respectively. Each of the capacitors CAP may include a bottom electrode BE disposed on each of the conductive patterns 165, a top electrode TE placed on the bottom electrode BE, and a dielectric layer 185 between the bottom electrode BE and the top electrode TE. The bottom electrode BE may have, for example, a hollow cylinder shape with one closed end or a cup shape. A bottom surface of the bottom electrode BE may be in contact with each of the conductive patterns 165. The top electrode TE may fill a space defined by an inner surface of the bottom electrode BE, and the dielectric layer 185 may extend between the inner surface of the bottom electrode BE and the top electrode TE. The bottom electrode BE may include at least one of doped polysilicon, metal nitride materials (e.g., titanium nitride), or metallic materials (e.g., tungsten, aluminum, and copper). The top electrode TE may be formed of or include at least one of doped poly-silicon, doped silicon germanium, metal nitride materials (e.g., titanium nitride), or metallic materials (e.g., tungsten, aluminum, and copper). The dielectric layer 185 may be formed of or include at least one of, for example, silicon oxide, silicon nitride, silicon oxynitride, and high-k dielectric materials (e.g., hafnium oxide).

A second upper insulating layer 180 may be disposed on the first upper insulating layer 170 to cover a space between the capacitors CAP. The second upper insulating layer 180 may be formed of or include at least one of, for example, silicon oxide, silicon nitride, and/or silicon oxynitride. A capping insulating layer 190 may be disposed on the second upper insulating layer 180 to cover top surfaces of the capacitors CAP. The capping insulating layer 190 may be formed of or include at least one of, for example, silicon oxide, silicon nitride, and/or silicon oxynitride.

According to an embodiment of the inventive concept, the paired vertical transistors may share the gate electrode GE, which is controlled by one of the first conductive lines 120, and may include the semiconductor patterns VSP, which are electrically connected to respective ones of the second conductive lines 140. Accordingly, it may be easy to independently control the operations of the paired vertical transistors. In addition, each of the semiconductor patterns VSP may have a vertical channel structure including the first and second source/drain regions SD1 and SD2, which are spaced apart from each other in the third direction D3, and the channel region CH, which is placed between the first and second source/drain regions SD1 and SD2. Accordingly, it may be possible to easily increase the integration density of the semiconductor device with the vertical channel transistors. Thus, it may be possible to realize the semiconductor device in which the operations of the vertical channel transistors can be easily controlled and the integration density can be easily increased.

In addition, each of the semiconductor patterns VSP may have a curved or bent shape that is extended along the side surface GE_S of the gate electrode GE in the direction parallel to the top surface 100U of the substrate 100. The inner side surface VSP_IS of each of the semiconductor patterns VSP may be a curved or bent surface that is provided to face the side surface GE_S of the gate electrode GE and is extended along the side surface GE_S of the gate electrode GE in the direction parallel to the top surface 100U of the substrate 100. Thus, it may be possible to easily increase an effective channel width of the vertical channel transistor including the semiconductor pattern VSP. In this case, it may be possible to improve the electrical characteristics of the vertical channel transistors in the semiconductor device.

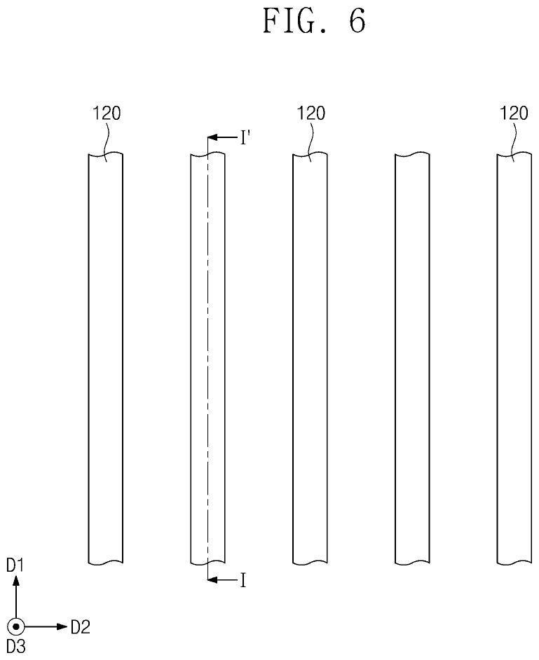

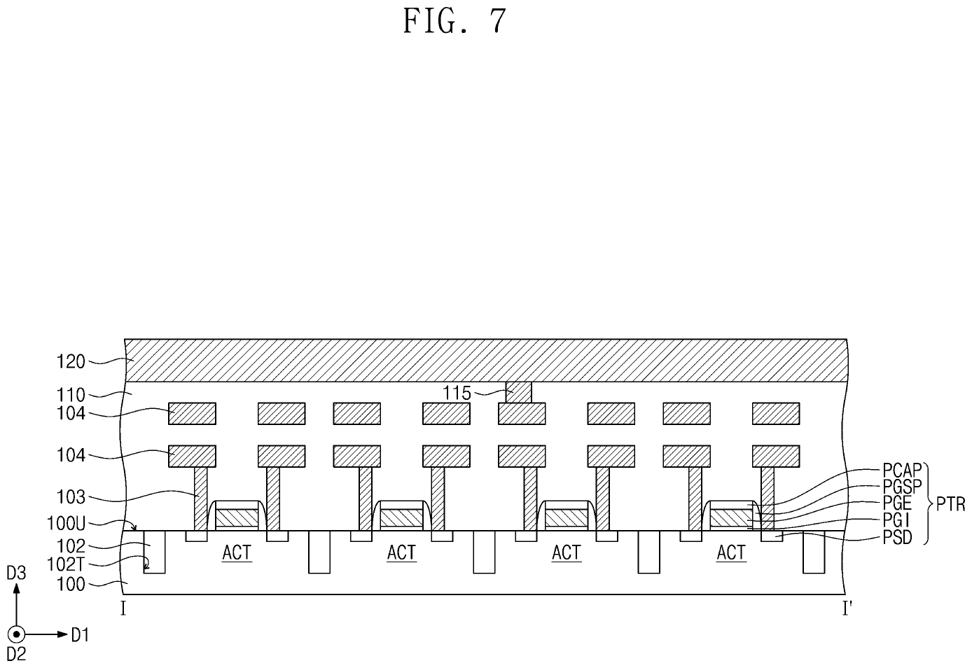

FIGS. 6, 8, 10, 12, 14, and 16 are plan views illustrating a method of fabricating a semiconductor device, according to an embodiment of the inventive concept. FIGS. 7, 9, 11, 13, 15, and 17 are sectional views taken along lines I-I′ of FIGS. 6, 8, 10, 12, 14, and 16, respectively. For the sake of brevity, an element previously described with reference to FIGS. 1 to 5 may be identified by the same reference number without repeating an overlapping description thereof.

Referring to FIGS. 6 and 7, device isolation patterns 102 may be formed in a substrate 100 to define active regions ACT. In an embodiment, the formation of the device isolation patterns 102 may include forming trenches 102T in the substrate 100 to define the active regions ACT, forming a device isolation layer on the substrate 100 to fill the trenches 102T, and planarizing the device isolation layer to expose a top surface of the substrate 100.

Peripheral transistors PTR may be formed on the active regions ACT of the substrate 100. Each of the peripheral transistors PTR may include a peripheral gate electrode PGE on a corresponding one of the active regions ACT, a peripheral gate insulating pattern PGI between the corresponding active region ACT and the peripheral gate electrode PGE, a peripheral capping pattern PCAP on the peripheral gate electrode PGE, peripheral gate spacers PGSP on side surfaces of the peripheral gate electrode PGE, and peripheral source/drain regions PSD formed in portions of the corresponding active region ACT at both sides of the peripheral gate electrode PGE.

Peripheral contacts 103 and peripheral interconnection lines 104 may be formed on the substrate 100. The peripheral contacts 103 may be electrically connected to the peripheral source/drain regions PSD of the peripheral transistors PTR, and the peripheral interconnection lines 104 may be electrically connected to the peripheral contacts 103. A peripheral insulating layer 110 may be formed on the substrate 100 to cover the peripheral transistors PTR, the peripheral contacts 103, and the peripheral interconnection lines 104.

First conductive lines 120 may be formed on the peripheral insulating layer 110. The first conductive lines 120 may extend in the first direction D1 and may be spaced apart from each other in the second direction D2. In an embodiment, the formation of the first conductive lines 120 may include forming a first conductive layer on the peripheral insulating layer 110, forming first mask patterns on the first conductive layer to define regions, in which the first conductive lines 120 will be formed, and etching the first conductive layer using the first mask patterns as an etch mask.

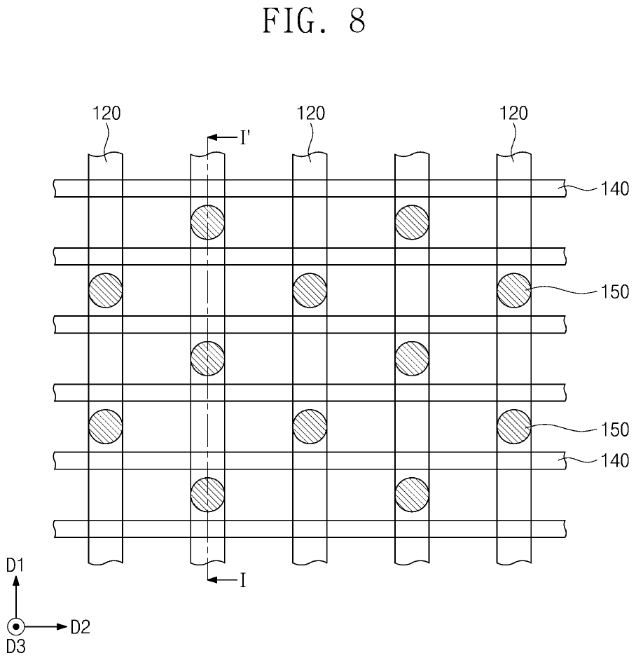

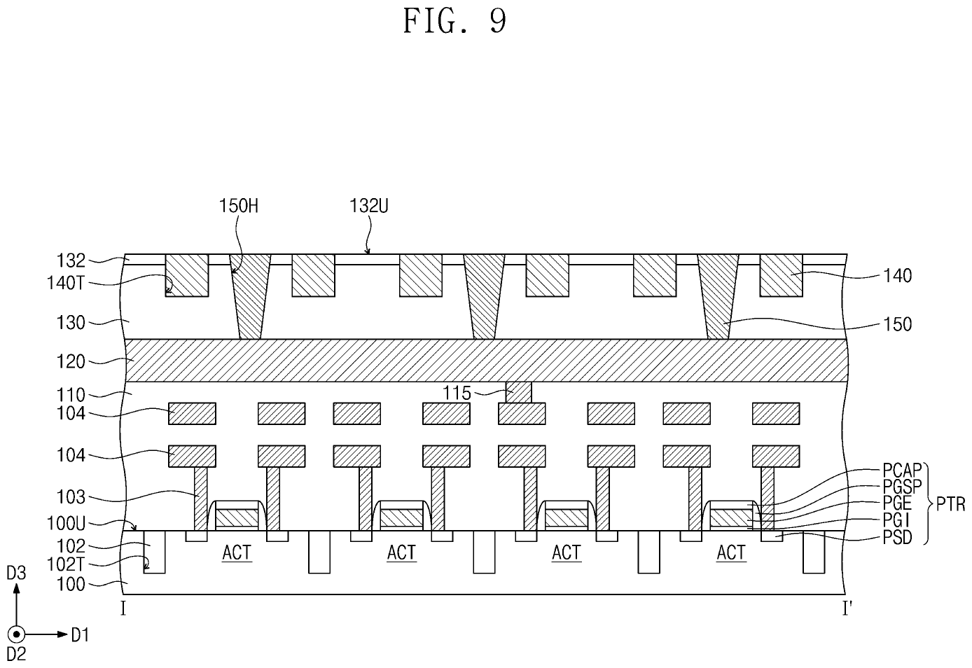

Referring to FIGS. 8 and 9, a first lower insulating layer 130 may be formed on the peripheral insulating layer 110 to cover the first conductive lines 120. A second lower insulating layer 132 may be formed on the first lower insulating layer 130. The second lower insulating layer 132 may be formed of a material different from the first lower insulating layer 130. The first lower insulating layer 130 and the second lower insulating layer 132 may be referred to as a lower insulating layer 130/132.

Second conductive lines 140 may be formed in the lower insulating layer 130/132. The second conductive lines 140 may extend in the second direction D2 and may be spaced apart from each other in the first direction D1. Each of the second conductive lines 140 may be provided to penetrate the second lower insulating layer 132 and may extend into the upper portion of the first lower insulating layer 130. In an embodiment, the formation of the second conductive lines 140 may include forming line trenches 140T, which are extended in the second direction D2 and are spaced apart from each other in the first direction D1, in the lower insulating layer 130/132, forming a second conductive layer on the lower insulating layer 130/132 to fill the line trenches 140T, and planarizing the second conductive layer to expose the top surface 132U of the lower insulating layer 130/132. Each of the line trenches 140T may be formed to penetrate the second lower insulating layer 132 and to extend in the upper portion of the first lower insulating layer 130. The top surface 132U of the lower insulating layer 130/132 may correspond to the top surface 132U of the second lower insulating layer 132.

Contact plugs 150 may be formed in the lower insulating layer 130/132 between the second conductive lines 140. The contact plugs 150 in the lower insulating layer 130/132 may be spaced apart from each other in the first and second directions D1 and D2. Each of the contact plugs 150 may be formed to penetrate the lower insulating layer 130/132 and may be electrically connected to a corresponding one of the first conductive lines 120. In an embodiment, the formation of the contact plugs 150 may include forming contact holes 150H in the lower insulating layer 130/132 between the second conductive lines 140, forming a contact conductive layer on the lower insulating layer 130/132 to fill the contact holes 150H, and planarizing the contact conductive layer to expose the top surface 132U of the lower insulating layer 130/132. The contact holes 150H in the lower insulating layer 130/132 may be spaced apart from each other in the first and second directions D1 and D2. Each of the contact holes 150H may be formed to penetrate the lower insulating layer 130/132 and expose a top surface of a corresponding one of the first conductive lines 120.

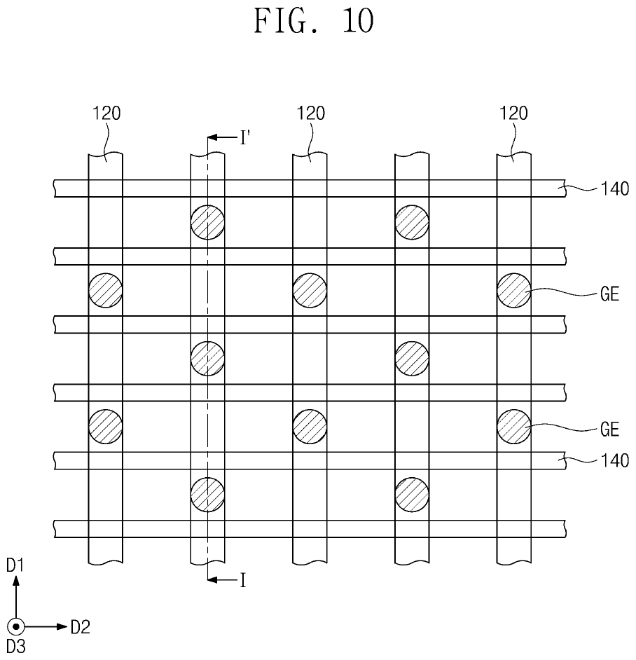

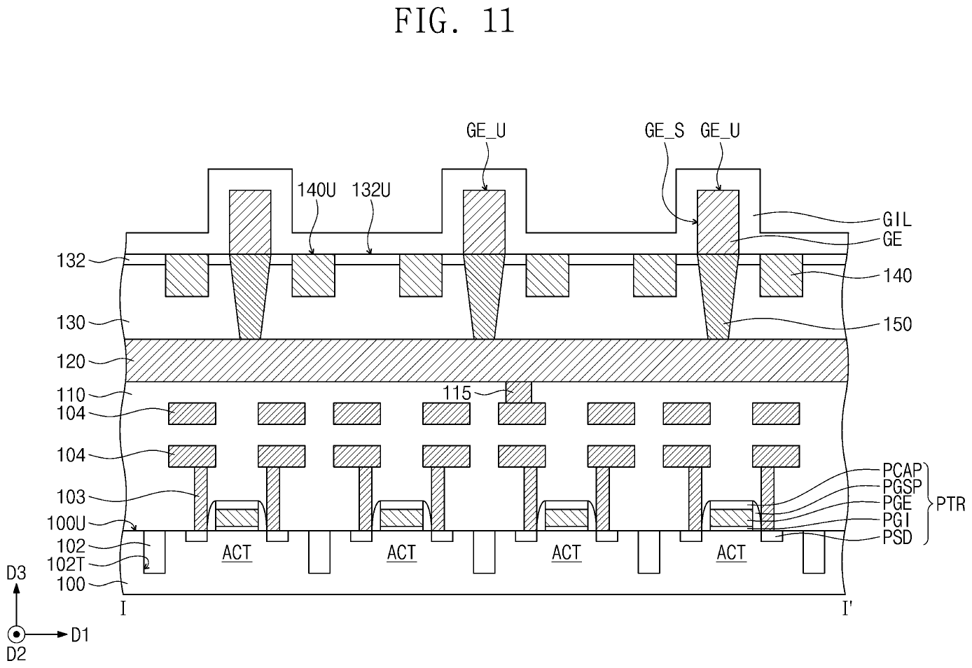

Referring to FIGS. 10 and 11, gate electrodes GE may be formed on the contact plugs 150, respectively. The gate electrodes GE may be spaced apart from each other in the first and second directions D1 and D2. In an embodiment, the formation of the gate electrodes GE may include forming a gate electrode layer on the second lower insulating layer 132, forming second mask patterns on the gate electrode layer to define regions, in which the gate electrodes GE will be formed, and etching the gate electrode layer using the second mask patterns as an etch mask.

A gate insulating layer GIL may be formed on the second lower insulating layer 132 to cover the gate electrodes GE. The gate insulating layer GIL may conformally cover the top and side surfaces GE_U and GE_S of each of the gate electrodes GE and may extend to the top surface 132U of the second lower insulating layer 132 and the top surfaces 140U of the second conductive lines 140. In an embodiment, the gate insulating layer GIL may be formed using a chemical vapor deposition method or a physical vapor deposition method.

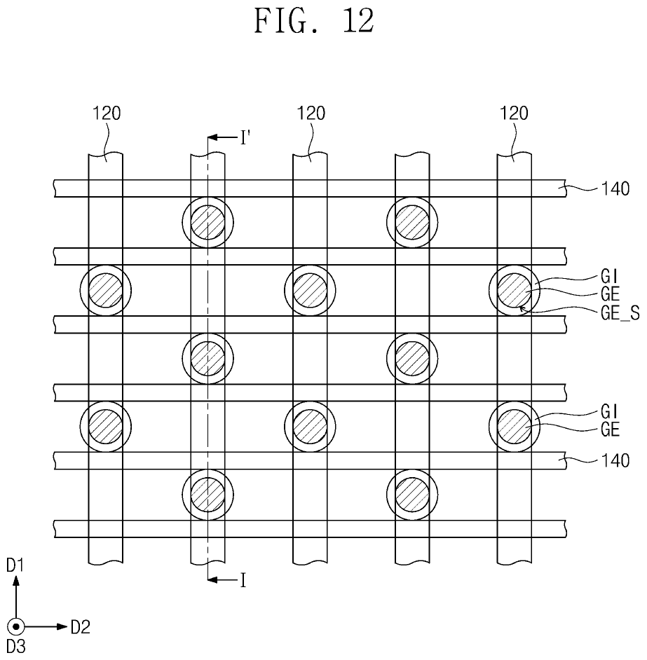

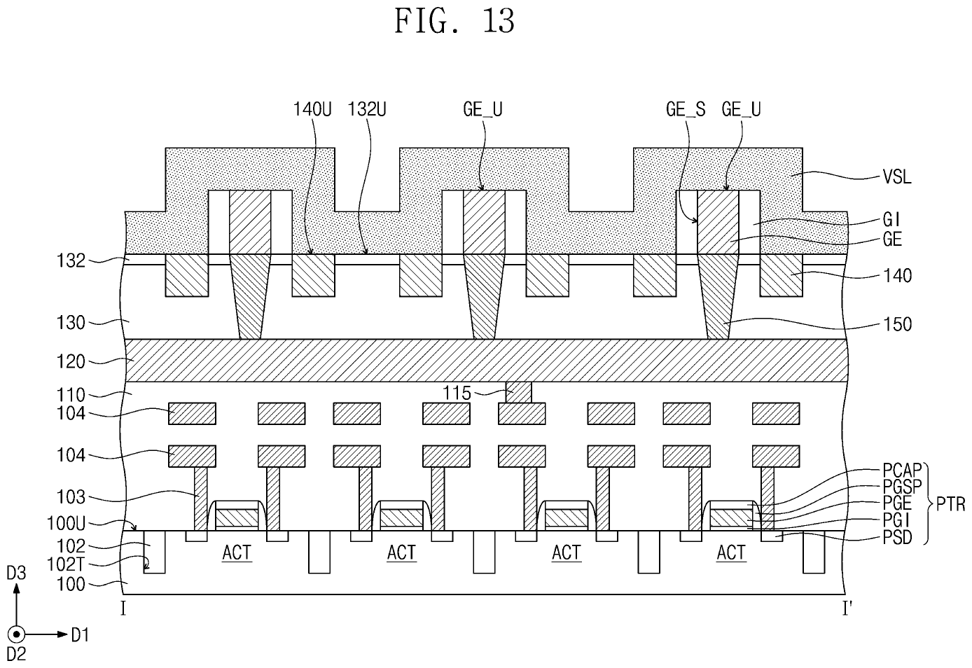

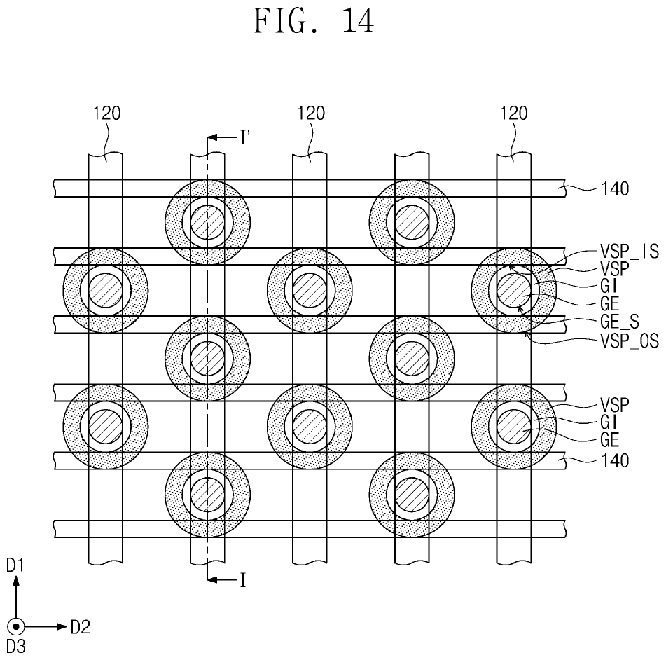

Referring to FIGS. 12 and 13, a first anisotropic etching process may be performed on the gate insulating layer GIL to locally form a gate insulating pattern GI on the side surface GE_S of each of the gate electrodes GE. As a result of the first anisotropic etching process, the top surface GE_U of each of the gate electrodes GE, the top surface 132U of the second lower insulating layer 132, and the top surfaces 140U of the second conductive lines 140 may be exposed. The gate insulating pattern GI may be a ring-shaped pattern that is provided to enclose the side surface GE_S of each of the gate electrodes GE in a direction parallel to the top surface 100U of the substrate 100.

A semiconductor layer VSL may be formed on the second lower insulating layer 132 to cover the gate electrodes GE and the gate insulating pattern GI. The semiconductor layer VSL may cover the top surface GE_U of each of the gate electrodes GE and may cover the gate insulating pattern GI on the side surface GE_S of each of the gate electrodes GE. The semiconductor layer VSL may extend to regions on the top surface 132U of the second lower insulating layer 132 and the top surfaces 140U of the second conductive lines 140. In an embodiment, the semiconductor layer VSL may be formed using a chemical vapor deposition method or a physical vapor deposition method.

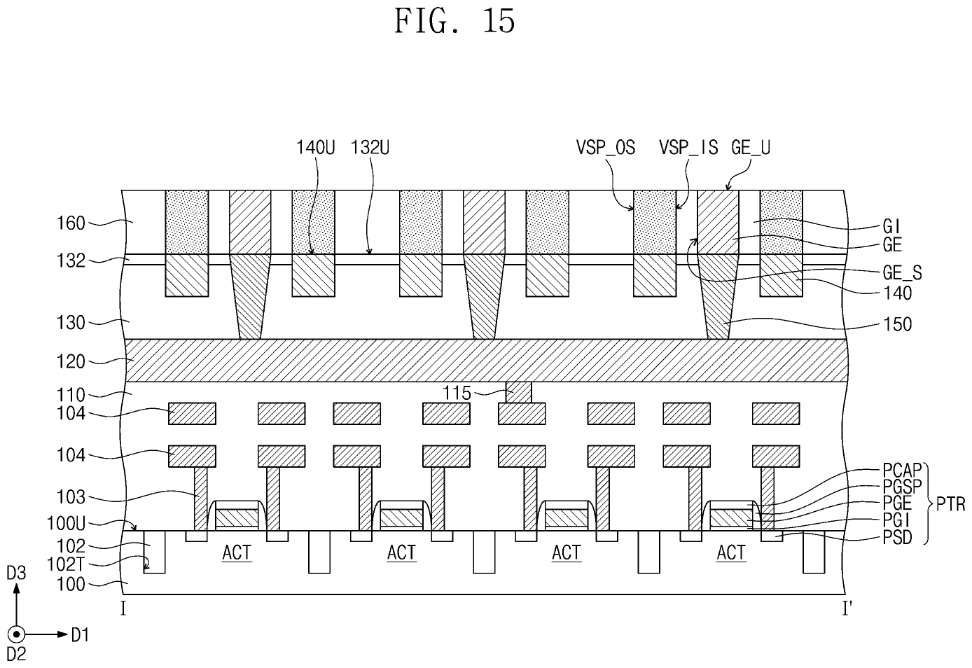

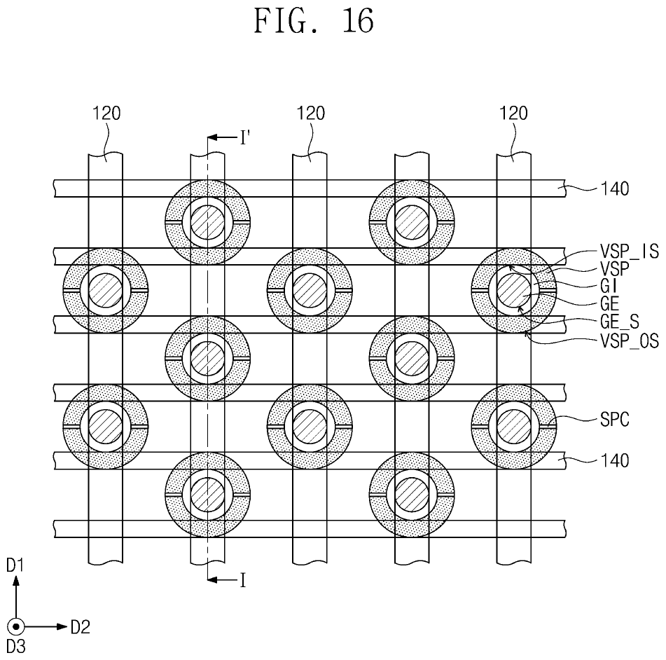

Referring to FIGS. 14 and 15, a second anisotropic etching process may be performed on the semiconductor layer VSL to locally form a semiconductor pattern VSP on the side surface GE_S of each of the gate electrodes GE. As a result of the second anisotropic etching process, the top surface GE_U of each of the gate electrodes GE and the top surface 132U of the second lower insulating layer 132 may be exposed. The semiconductor pattern VSP may be in contact with top surfaces 140U of a pair of second conductive lines 140, which are selected from the second conductive lines 140 to be the closest to each other in the first direction D1. The semiconductor pattern VSP may be a ring-shaped pattern that is provided to enclose the side surface GE_S of each of the gate electrodes GE in the direction parallel to the top surface 100U of the substrate 100.

The gate insulating pattern GI may extend between the side surface GE_S of each of the gate electrodes GE and the semiconductor pattern VSP. The semiconductor pattern VSP may have an inner side surface VSP_IS, which faces the side surface GE_S of each of the gate electrodes GE, and an outer side surface VSP_OS, which is opposite to the inner side surface VSP_IS. The inner side surface VSP_IS of the semiconductor pattern VSP may be in contact with the gate insulating pattern GI.

According to an embodiment of the inventive concept, since the semiconductor layer VSL is formed on the gate insulating pattern GI using a deposition method, the inner side surface VSP_IS of the semiconductor pattern VSP adjacent to the gate insulating pattern GI may not be exposed to the second anisotropic etching process. Thus, a defect caused by the etching process may not occur on the inner side surface VSP_IS of the semiconductor pattern VSP, and as a result, it may be possible to prevent a defect from being produced in an effective channel region of the semiconductor pattern VSP. Accordingly, the vertical channel transistor including the semiconductor pattern VSP may be formed to have improved electrical characteristics. A gap-fill insulating layer 160 may be formed on the second lower insulating layer 132 to fill a space between adjacent ones of the semiconductor patterns VSP. The gap-fill insulating layer 160 may cover the outer side surface VSP_OS of the semiconductor pattern VSP.

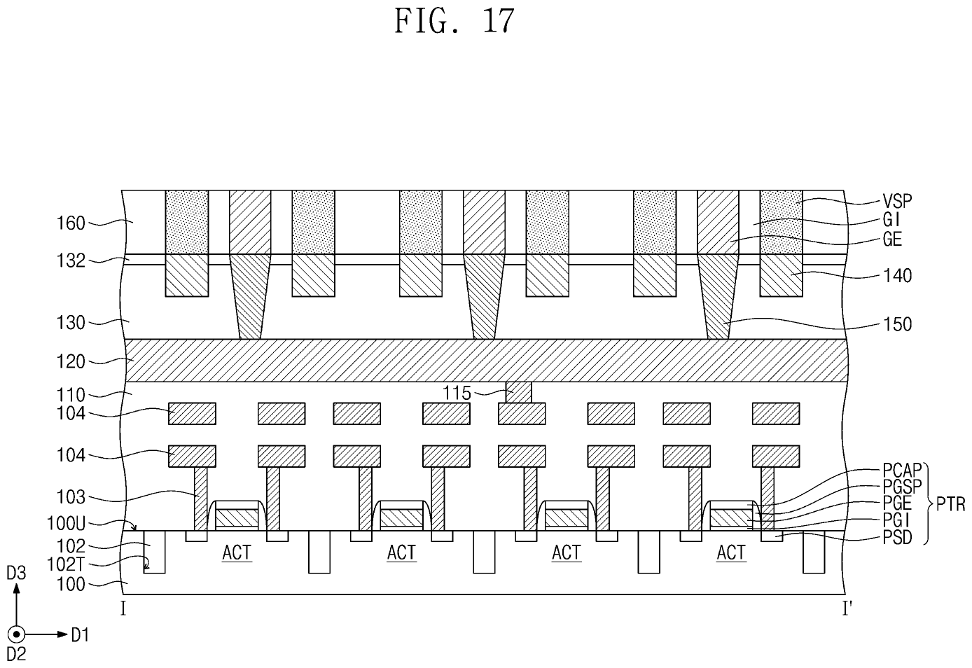

Referring to FIGS. 16 and 17, a separation patterns SPC may be formed to penetrate the semiconductor pattern VSP. In the semiconductor pattern VSP, the separation patterns SPC may be spaced apart from each other along the second direction D2, and the semiconductor pattern VSP may be divided into a pair of semiconductor patterns VSP, which are spaced apart from each other in the first direction D1, by the separation patterns SPC. The paired semiconductor patterns VSP may be electrically connected to the paired second conductive lines 140, respectively.

Referring back to FIGS. 3 and 4, conductive patterns 165 may be formed on the semiconductor patterns VSP, respectively. In an embodiment, the formation of the conductive patterns 165 may include forming a conductive layer on the gap-fill insulating layer 160 to cover the semiconductor patterns VSP, forming third mask patterns on the conductive layer to define regions, in which the conductive patterns 165 will be formed, and etching the conductive layer using the third mask patterns as an etch mask. The conductive patterns 165 may be in contact with the top surfaces VSP_U of the semiconductor patterns VSP, respectively.

A first upper insulating layer 170 may be formed on the gap-fill insulating layer 160 to fill a space between the conductive patterns 165. A second upper insulating layer 180 may be formed on the first upper insulating layer 170, and capacitors CAP may be formed in the second upper insulating layer 180. The capacitors CAP may be electrically connected to the conductive patterns 165, respectively. Each of the capacitors CAP may include a bottom electrode BE disposed on each of the conductive patterns 165, a top electrode TE placed on the bottom electrode BE, and a dielectric layer 185 between the bottom electrode BE and the top electrode TE.

In an embodiment, the formation of the capacitors CAP may include forming a capacitor hole in the second upper insulating layer 180 to expose each of the conductive patterns 165, forming the bottom electrode BE to fill a portion of the capacitor hole and conformally cover an inner surface of the capacitor hole, forming the dielectric layer 185 to fill a portion of the capacitor hole and conformally cover an inner surface of the bottom electrode BE, and forming the top electrode TE to fill a remaining portion of the capacitor hole. Thereafter, a capping insulating layer 190 may be formed on the second upper insulating layer 180 to cover top surfaces of the capacitors CAP.

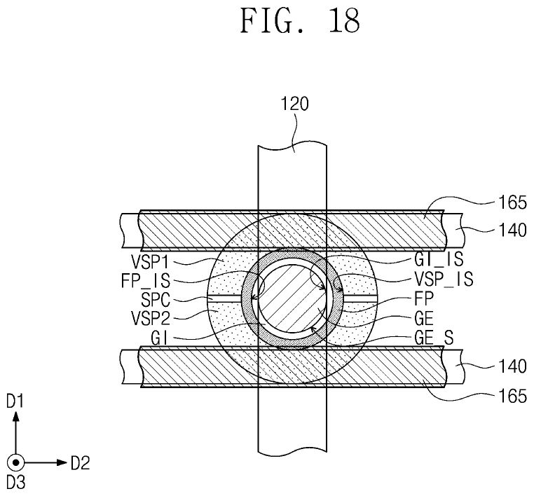

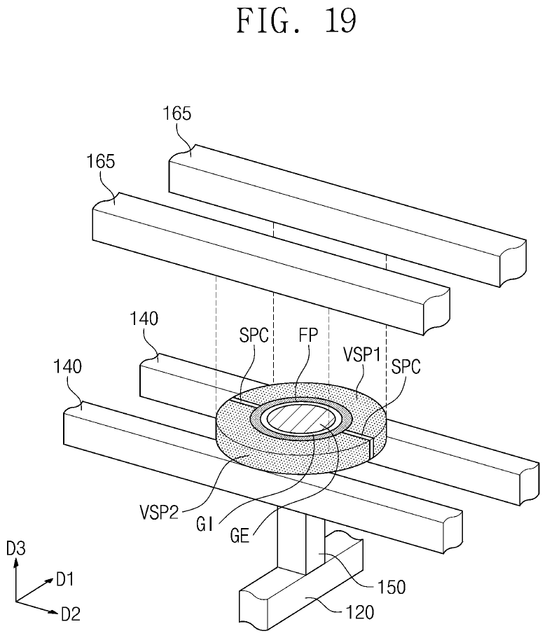

FIG. 18 is a plan view illustrating a semiconductor device according to an embodiment of the inventive concept, and FIG. 19 is a perspective view schematically illustrating a semiconductor device of FIG. 18. For the sake of brevity, features, which are different from the semiconductor device described with reference to FIGS. 1 and 2, will be mainly described below.

Referring to FIGS. 18 and 19, a ferroelectric pattern FP may extend between each of the semiconductor patterns VSP1 and VSP2 and the gate insulating pattern GI. The ferroelectric pattern FP may be a curved or bent pattern, which is extended along the side surface GE_S of the gate electrode GE, when viewed in a plan view. The ferroelectric pattern FP may have a ring-shaped pattern that is provided to enclose the side surface GE_S of the gate electrode GE, when viewed in a plan view. An inner side surface FP_IS of the ferroelectric pattern FP may face the side surface GE_S of the gate electrode GE and may be spaced apart from the side surface GE_S of the gate electrode GE with the gate insulating pattern GI extending therebetween. The inner side surface FP_IS of the ferroelectric pattern FP may be in contact with the gate insulating pattern GI. The inner side surface FP_IS of the ferroelectric pattern FP may be a curved or bent surface, which is extended along the side surface GE_S of the gate electrode GE, when viewed in a plan view.

The separation patterns SPC may extend between the semiconductor patterns VSP1 and VSP2 and may be spaced apart from each other in the second direction D2. The gate electrode GE, the gate insulating pattern GI, and the ferroelectric pattern FP may extend between the separation patterns SPC. The semiconductor patterns VSP1 and VSP2 and the separation patterns SPC may enclose the gate electrode GE, the gate insulating pattern GI, and the ferroelectric pattern FP, when viewed in a plan view.

Conductive patterns 165 may be disposed on the semiconductor patterns VSP1 and VSP2, respectively. The conductive patterns 165 may be spaced apart from each other in the first direction D1 and may extend in the second direction D2. The conductive patterns 165 may extend to be parallel to the second conductive lines 140. The conductive patterns 165 may be electrically connected to the semiconductor patterns VSP1 and VSP2, respectively.

In an embodiment, the gate electrode GE may be electrically connected to the first conductive line 120 through the contact plug 150, and the first conductive line 120 may serve as a word line. The gate electrode GE, the gate insulating pattern GI, the ferroelectric pattern FP, and the semiconductor patterns VSP1 and VSP2 may constitute a pair of vertical channel transistors. The paired vertical channel transistors may share the gate electrode GE, the gate insulating pattern GI, and the ferroelectric pattern FP, and may include the semiconductor patterns VSP1 and VSP2, respectively. Each of the semiconductor patterns VSP1 and VSP2 may be used as a vertical channel of each of the paired vertical channel transistors. The second conductive lines 140 may be electrically connected to the semiconductor patterns VSP1 and VSP2, respectively, and may be used as bit (or source) lines. The conductive patterns 165 may be electrically connected to the semiconductor patterns VSP1 and VSP2, respectively, and may be used as source (or bit) lines. Each of the second conductive lines 140 and each of the conductive patterns 165 may be electrically connected to source/drain terminals of each of the paired vertical channel transistors. Each of the paired vertical channel transistors may constitute a ferroelectric random access memory (FeRAM) cell.

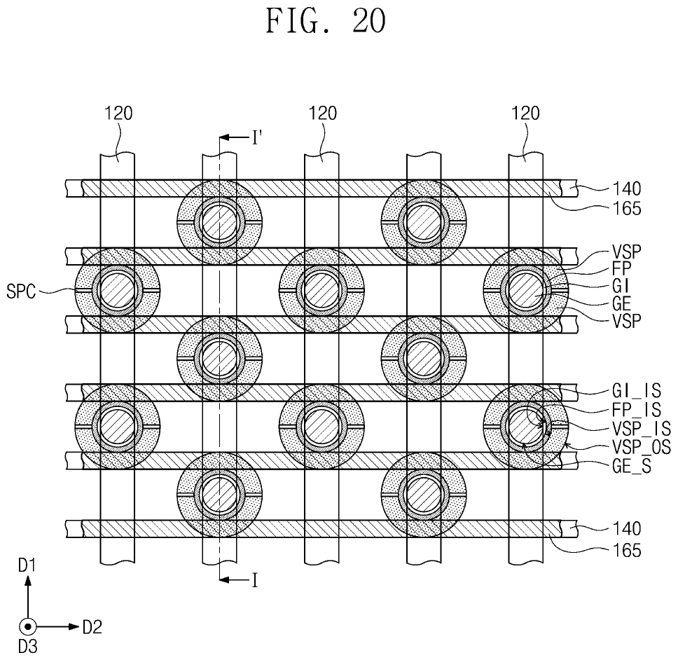

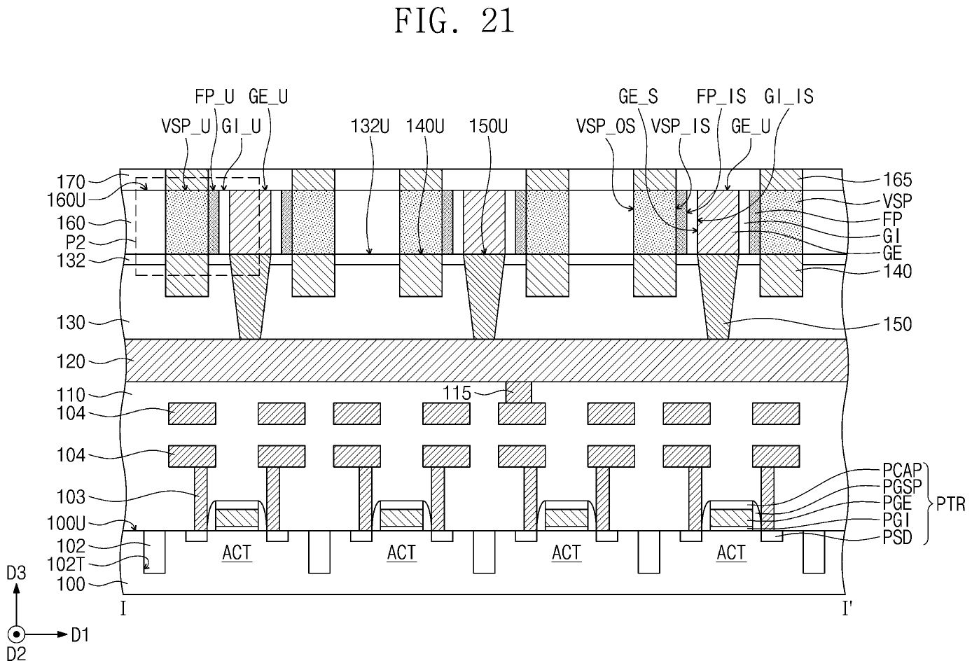

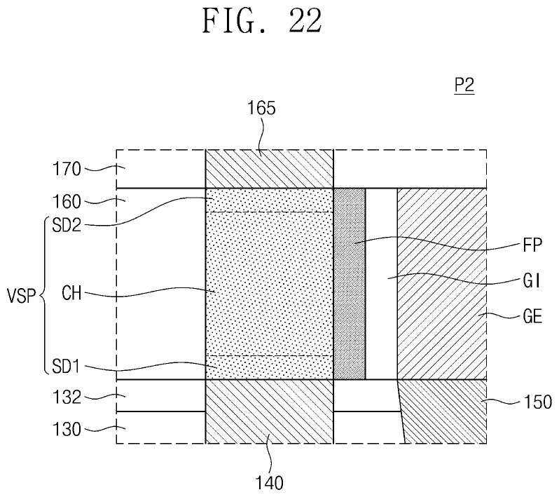

FIG. 20 is a plan view illustrating a semiconductor device according to an embodiment of the inventive concept, and FIG. 21 is a sectional view taken along a line I-I′ of FIG. 20. FIG. 22 is an enlarged view illustrating a portion ‘P2’ of FIG. 21. For the sake of brevity, features, which are different from the semiconductor device described with reference to FIGS. 3 to 5, will be mainly described below.

Referring to FIGS. 20 and 21, the peripheral transistors PTR may constitute a peripheral circuit, which is used to operate or drive a FeRAM cell according to an embodiment of the inventive concept. The first conductive lines 120 may be disposed on the peripheral insulating layer 110. The first conductive lines 120 may extend in the first direction D1 and may be spaced apart from each other in the second direction D2. Each of the first conductive lines 120 may be electrically connected to a corresponding one of the peripheral interconnection lines 104 through the lower contact 115.

The first lower insulating layer 130 may be disposed on the peripheral insulating layer 110 to cover the first conductive lines 120. The second lower insulating layer 132 may be disposed on the first lower insulating layer 130. The first lower insulating layer 130 and the second lower insulating layer 132 may be referred to as a lower insulating layer 130/132. The second conductive lines 140 may be disposed in the lower insulating layer 130/132 and on the first conductive lines 120. The second conductive lines 140 may extend in the second direction D2 and may be spaced apart from each other in the first direction D1. The second conductive lines 140 may be provided to cross the first conductive lines 120.

The contact plugs 150 may be disposed in the lower insulating layer 130/132 between the second conductive lines 140. In the lower insulating layer 130/132, the contact plugs 150 may be spaced apart from each other in the first and second directions D1 and D2. Each of the contact plugs 150 may be positioned between a pair of second conductive lines 140, which are selected from the second conductive lines 140 to be the closest to each other in the first direction D1. Between the paired second conductive lines 140, each of the contact plugs 150 may be provided to penetrate the lower insulating layer 130/132 and may be electrically connected to a corresponding one of the first conductive lines 120. The gate electrodes GE may be disposed on and electrically connected to the contact plugs 150, respectively. The gate electrodes GE may be spaced apart from each other in the first and second directions D1 and D2.

The semiconductor patterns VSP may be disposed at both sides of each of the gate electrodes GE. The semiconductor patterns VSP may be spaced apart from each other in the first direction D1 with each of the gate electrodes GE extending therebetween. The semiconductor patterns VSP may be respectively disposed on a pair of second conductive lines 140, which are selected from the second conductive lines 140 to be the closest to each other in the first direction D1, and may be electrically connected to the paired second conductive lines 140, respectively.

The gate insulating pattern GI may extend between each of the gate electrodes GE and each of the semiconductor patterns VSP. The gate insulating pattern GI may be a curved or bent pattern that is extended along the side surface GE_S of each of the gate electrodes GE in a direction parallel to the top surface 100U of the substrate 100. The gate insulating pattern GI may be a ring-shaped pattern that is provided to enclose the side surface GE_S of each of the gate electrodes GE in the direction parallel to the top surface 100U of the substrate 100.

In an embodiment, a ferroelectric pattern FP may be provided to extend between each of the semiconductor patterns VSP and the gate insulating pattern GI. The ferroelectric pattern FP may be a curved or bent pattern that is extended along the side surface GE_S of each of the gate electrodes GE in a direction parallel to the top surface 100U of the substrate 100. The ferroelectric pattern FP may be a ring-shaped pattern that is provided to enclose the side surface GE_S of each of the gate electrodes GE in the direction parallel to the top surface 100U of the substrate 100. The inner side surface FP_IS of the ferroelectric pattern FP may face the side surface GE_S of each of the gate electrodes GE and may be in contact with the gate insulating pattern GI. The inner side surface FP_IS of the ferroelectric pattern FP may be a curved or bent surface that is extended along the side surface GE_S of each of the gate electrodes GE in the direction parallel to the top surface 100U of the substrate 100.

The ferroelectric pattern FP may include hafnium oxide with a ferroelectric property. The ferroelectric pattern FP may further include dopants, and in an embodiment, the dopants may be at least one of Zr, Si, Al, Y, Gd, La, Sc, or Sr. The ferroelectric pattern FP may be formed of or include, for example, HfO₂, HfZnO, HfSiO, HfSiON, HfTaO, HfTIO, HfZrO or combinations thereof. The ferroelectric pattern FP may have an orthorhombic phase. The ferroelectric pattern FP may have a laminated structure, in which ferroelectric layers of at least two different kinds are stacked, or a laminated structure, in which at least one ferroelectric layer and at least one insulating layer are stacked.

Each of the semiconductor patterns VSP may be a curved or bent pattern that is extended along the side surface GE_S of each of the gate electrodes GE in the direction parallel to the top surface 100U of the substrate 100. The inner side surface VSP_IS of each of the semiconductor patterns VSP may face the side surface GE_S of each of the gate electrodes GE and may be in contact with the ferroelectric pattern FP. The inner side surface VSP_IS of each of the semiconductor patterns VSP may be a curved or bent surface that is extended along the side surface GE_S of each of the gate electrodes GE in the direction parallel to the top surface 100U of the substrate 100.

The separation patterns SPC may extend between the semiconductor patterns VSP. Between the semiconductor patterns VSP, the separation patterns SPC may be spaced apart from each other in the second direction D2. Each of the gate electrodes GE, the gate insulating pattern GI, and the ferroelectric pattern FP may extend between the separation patterns SPC. The semiconductor patterns VSP and the separation patterns SPC may enclose each of the gate electrodes GE, the gate insulating pattern GI, and the ferroelectric pattern FP in the direction parallel to the top surface 100U of the substrate 100.

Each of the gate electrodes GE, the gate insulating pattern GI, the ferroelectric pattern FP, and the semiconductor patterns VSP may constitute a pair of vertical channel transistors. Each of the semiconductor patterns VSP may serve as a vertical channel of each of the paired vertical channel transistors. The paired vertical channel transistors may share each of the gate electrodes GE.

The gap-fill insulating layer 160 may be disposed on the second lower insulating layer 132 and may fill a space between the paired vertical channel transistors and another pair of vertical channel transistors adjacent thereto. The gap-fill insulating layer 160 may cover the outer side surface VSP_OS of each of the semiconductor patterns VSP. The gap-fill insulating layer 160 may fill a space between the outer side surfaces VSP_OS of the semiconductor patterns VSP.

Conductive patterns 165 may be disposed on and electrically connected to the semiconductor patterns VSP, respectively. In an embodiment, the conductive patterns 165 may extend in the second direction D2 and may be spaced apart from each other in the first direction D1. The conductive patterns 165 may extend to be parallel to the second conductive lines 140. Each of the conductive patterns 165 may be commonly electrically connected to the semiconductor patterns VSP, which are arranged in the second direction D2.

Referring to FIGS. 21 and 22, each of the semiconductor patterns VSP may include a first source/drain region SD1, which is adjacent to each of the second conductive lines 140, a second source/drain region SD2, which is adjacent to each of the conductive patterns 165, and a channel region CH between the first and second source/drain regions SD1 and SD2. The first and second source/drain regions SD1 and SD2 may be spaced apart from each other in the third direction D3, and the channel region CH may be a vertical channel region, which is extended in the third direction D3. Each of the gate electrodes GE, the gate insulating pattern GI, the ferroelectric pattern FP, and each of the semiconductor patterns VSP may form a vertical channel transistor, and each of the semiconductor patterns VSP may serve as a vertical channel region of the vertical channel transistor.

Referring to FIGS. 20 and 21, a first upper insulating layer 170 may be disposed on the gap-fill insulating layer 160 to fill a space between the conductive patterns 165. In an embodiment, the capacitors CAP described with reference to FIGS. 3 and 4 may be omitted.

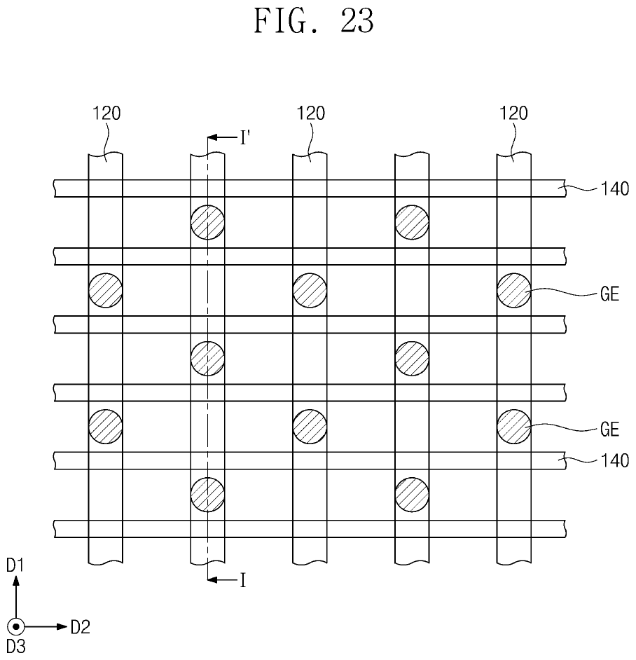

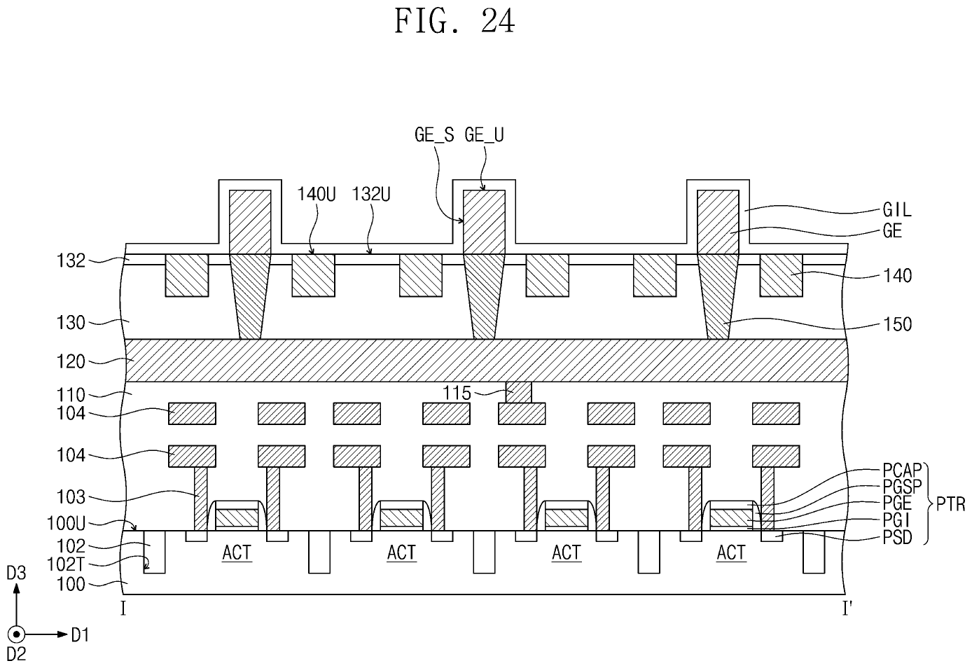

FIGS. 23, 25, and 27 are plan views illustrating a method of fabricating a semiconductor device, according to an embodiment of the inventive concept. FIGS. 24, 26, and 28 are sectional views taken along lines I-I′ of FIGS. 23, 25, and 27, respectively. For the sake of brevity, features, which are different from the fabrication method described with reference to FIGS. 6 to 17, will be mainly described below.

Referring to FIGS. 23 and 24, the device isolation patterns 102 may be formed in the substrate 100 to define the active regions ACT. The peripheral transistors PTR may be formed on the active regions ACT of the substrate 100, and the peripheral contacts 103 and the peripheral interconnection lines 104 may be formed on the substrate 100. The peripheral insulating layer 110 may be formed on the substrate 100 to cover the peripheral transistors PTR, the peripheral contacts 103, and the peripheral interconnection lines 104.

The first conductive lines 120 may be formed on the peripheral insulating layer 110. The first conductive lines 120 may extend in the first direction D1 and may be spaced apart from each other in the second direction D2. The first lower insulating layer 130 may be formed on the peripheral insulating layer 110 to cover the first conductive lines 120. The second lower insulating layer 132 may be formed on the first lower insulating layer 130.

The second conductive lines 140 may be formed in the lower insulating layer 130/132. The second conductive lines 140 may extend in the second direction D2 and may be spaced apart from each other in the first direction D1. The contact plugs 150 may be formed in the lower insulating layer 130/132 between the second conductive lines 140. In the lower insulating layer 130/132, the contact plugs 150 may be spaced apart from each other in the first and second directions D1 and D2. The gate electrodes GE may be formed on the contact plugs 150, respectively. The gate electrodes GE may be spaced apart from each other in the first and second directions D1 and D2.

A gate insulating layer GIL may be formed on the second lower insulating layer 132 to cover the gate electrodes GE. The gate insulating layer GIL may conformally cover the top and side surfaces GE_U and GE_S of each of the gate electrodes GE and may extend to the top surface 132U of the second lower insulating layer 132 and the top surfaces 140U of the second conductive lines 140. In an embodiment, the gate insulating layer GIL may be formed using a chemical vapor deposition method or a physical vapor deposition method.

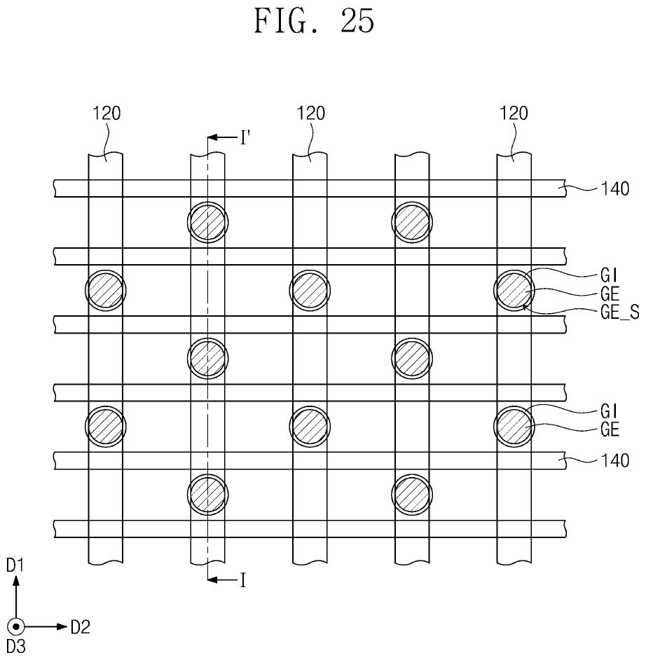

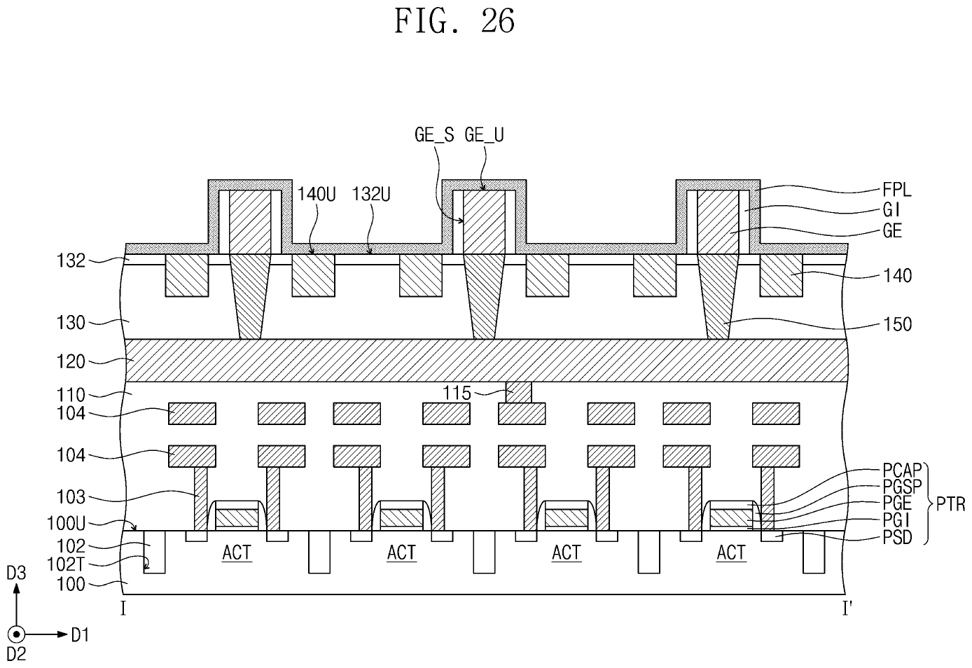

Referring to FIGS. 25 and 26, a first anisotropic etching process may be performed on the gate insulating layer GIL to locally form a gate insulating pattern GI on the side surface GE_S of each of the gate electrodes GE. As a result of the first anisotropic etching process, the top surface GE_U of each of the gate electrodes GE, the top surface 132U of the second lower insulating layer 132, and the top surfaces 140U of the second conductive lines 140 may be exposed. The gate insulating pattern GI may be a ring-shaped pattern that is provided to enclose the side surface GE_S of each of the gate electrodes GE in a direction parallel to the top surface 100U of the substrate 100.

A ferroelectric layer FPL may be formed on the second lower insulating layer 132 to cover the gate electrodes GE and the gate insulating pattern GI. The ferroelectric layer FPL may cover the top surface GE_U of each of the gate electrodes GE and may cover the gate insulating pattern GI on the side surface GE_S of each of the gate electrodes GE. The ferroelectric layer FPL may extend to regions on the top surface 132U of the second lower insulating layer 132 and the top surfaces 140U of the second conductive lines 140. In an embodiment, the ferroelectric layer FPL may be formed using a chemical vapor deposition method or a physical vapor deposition method.

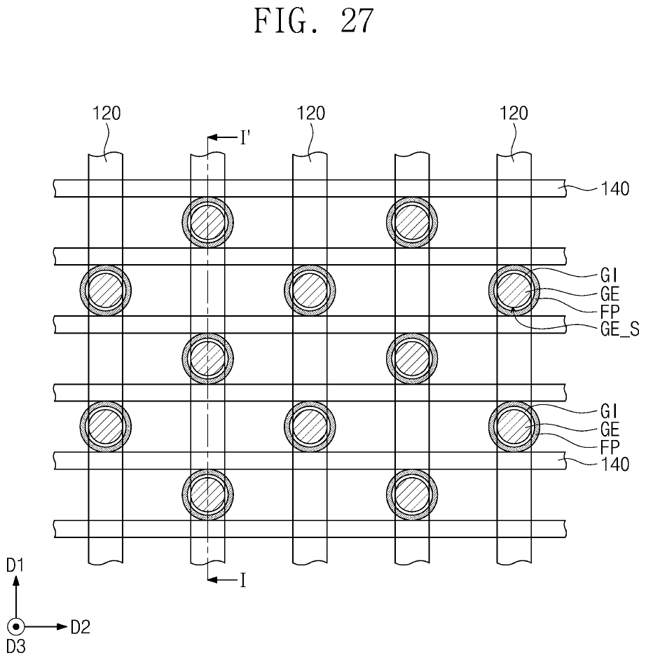

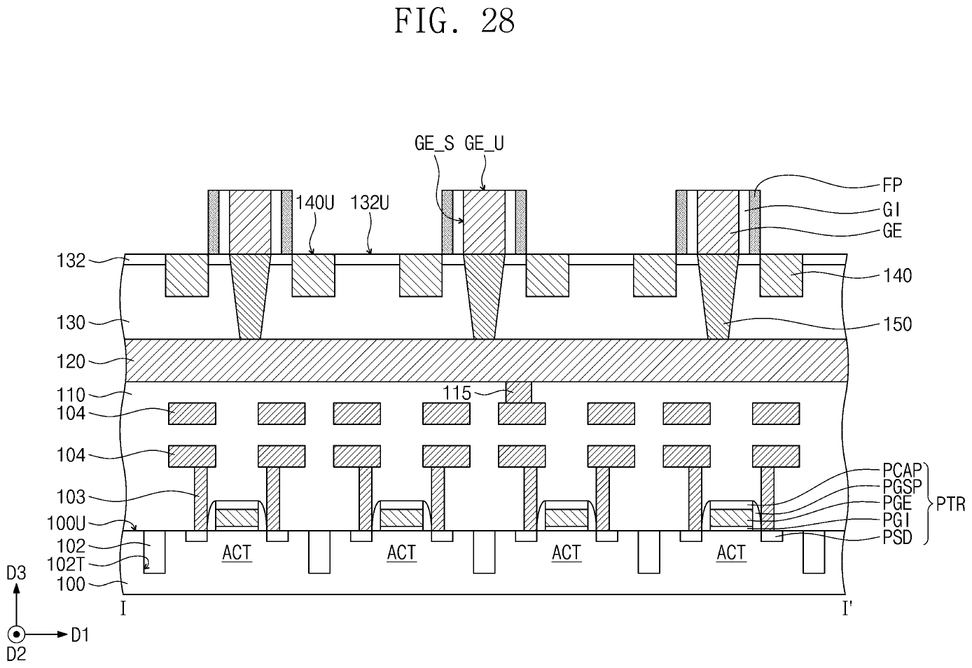

Referring to FIGS. 27 and 28, a third anisotropic etching process may be performed on the ferroelectric layer FPL to locally form a ferroelectric pattern FP on the side surface GE_S of each of the gate electrodes GE. As a result of the third anisotropic etching process, the top surface GE_U of each of the gate electrodes GE, the top surface 132U of the second lower insulating layer 132 and the top surfaces 140U of the second conductive lines 140 may be exposed. The ferroelectric pattern FP may be a ring-shaped pattern that is provided to enclose the side surface GE_S of each of the gate electrodes GE in a direction parallel to the top surface 100U of the substrate 100. Except for the features described above, the fabrication method according to the present embodiment may be substantially the same as the fabrication method with reference to FIGS. 6 to 17.

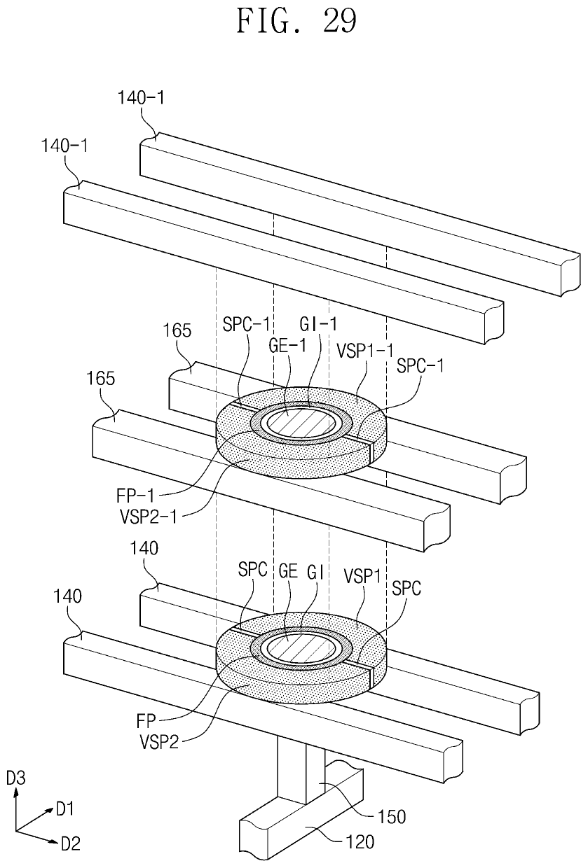

FIG. 29 is a perspective view schematically illustrating a semiconductor device according to an embodiment of the inventive concept. For the sake of brevity, features, which are different from the semiconductor device described with reference to FIGS. 18 and 19, will be mainly described below. Referring to FIG. 29, an additional gate electrode GE-1 may be disposed on the gate electrode GE and may be electrically connected to the gate electrode GE through an additional contact plug (not shown). Additional semiconductor patterns VSP1-1 and VSP2-1 may be disposed on the conductive patterns 165, respectively, and may be spaced apart from each other in the first direction D1. The additional semiconductor patterns VSP1-1 and VSP2-1 may be electrically connected to the conductive patterns 165, respectively. An additional gate insulating pattern GI-1 may extend between each of the additional semiconductor patterns VSP1-1 and VSP2-1 and the additional gate electrode GE-1. An additional ferroelectric pattern FP-1 may extend between each of the additional semiconductor patterns VSP1-1 and VSP2-1 and the additional gate insulating pattern GI-1.

Additional second conductive lines 140-1 may be disposed on the additional semiconductor patterns VSP1-1 and VSP2-1, respectively. The additional second conductive lines 140-1 may be spaced apart from each other in the first direction D1 and may extend in the second direction D2. The additional second conductive lines 140-1 may extend to be parallel to the conductive patterns 165. The additional second conductive lines 140-1 may be electrically connected to the additional semiconductor patterns VSP1-1 and VSP2-1, respectively.

In an embodiment, the gate electrode GE and the additional gate electrode GE-1 may be electrically connected to the first conductive line 120 through the contact plug 150 and the additional contact plug, and the first conductive line 120 may serve as a word line. The gate electrode GE, the gate insulating pattern GI, the ferroelectric pattern FP, and the semiconductor patterns VSP1 and VSP2 may form a first pair of vertical channel transistors, and the additional gate electrode GE-1, the additional gate insulating pattern GI-1, the additional ferroelectric pattern FP-1, and the additional semiconductor patterns VSP1-1 and VSP2-1 may form a second pair of vertical channel transistors. The second pair of vertical channel transistors may be stacked on the first pair of vertical channel transistors vertically (e.g., in the third direction D3).

The second conductive lines 140 may be electrically connected to the semiconductor patterns VSP1 and VSP2, respectively, and may serve as bit lines. The conductive patterns 165 may be electrically connected to the semiconductor patterns VSP1 and VSP2, respectively, and may serve as source lines. The conductive patterns 165 may be electrically connected to the additional semiconductor patterns VSP1-1 and VSP2-1, respectively. The semiconductor patterns VSP1 and VSP2 and the additional semiconductor patterns VSP1-1 and VSP2-1 may share the conductive patterns 165, and the conductive patterns 165 may serve as common source lines. The additional second conductive lines 140-1 may be electrically connected to the additional semiconductor patterns VSP1-1 and VSP2-1, respectively, and may serve as additional bit lines.

According to an embodiment of the inventive concept, vertical transistors paired may share a gate electrode, which is controlled by one first conductive line, and may include semiconductor patterns, respectively, which are electrically connected to respective ones of second conductive lines semiconductor patterns. Accordingly, it may be easy to independently control the operations of the paired vertical transistors. In addition, each of the semiconductor patterns may have a vertical channel structure including first and second source/drain regions, which are spaced apart from each other in a vertical direction, and a channel region, which is provided between the first and second source/drain regions. Accordingly, it may be possible to easily increase the integration density of the semiconductor device with the vertical channel transistors. Thus, it may be possible to realize the semiconductor device in which the operations of the vertical channel transistors can be easily controlled and the integration density can be easily increased, and the fabrication method thereof.

Furthermore, each of the semiconductor patterns may be a curved or bent pattern that is extended along a side surface of the gate electrode in a horizontal direction. Each of the semiconductor patterns may have an inner side surface that is provided to face the side surface of the gate electrode and is a curved or bent surface extended along the side surface of the gate electrode in the horizontal direction. Thus, it may be possible to easily increase an effective channel width of the vertical channel transistor including the semiconductor pattern. The inner side surface of each of the semiconductor patterns may not be exposed to an etching process, which is performed to form the semiconductor patterns, and thus, it may be possible to prevent a defect, which is caused by the etching process, from being produced in an effective channel region of each of the semiconductor patterns. As a result, it may be possible to realize a semiconductor device, which includes the vertical channel transistors with improved electrical characteristics, and a method of fabricating the same.

While example embodiments of the inventive concept have been particularly shown and described, it will be understood by one of ordinary skill in the art that variations in form and detail may be made therein without departing from the spirit and scope of the attached claims.

1. A semiconductor device, comprising:
a substrate having a pair of second conductive lines thereon;
a first conductive line extending between the pair of second conductive lines and the substrate;
a contact plug that extends between the pair of second conductive lines and is electrically connected to the first conductive line;
a gate electrode on the contact plug;
first and second semiconductor patterns extending on first and second ones of the pair of second conductive lines, respectively;
a gate insulating pattern extending between each of the first and second semiconductive patterns and the gate electrode; and
first and second conductive patterns extending on the first and second semiconductor patterns, respectively.

2. The device of claim 1, wherein the first and second conductive patterns are electrically connected to a capacitor electrode of a first capacitor and a capacitor electrode of a second capacitor, respectively; wherein the first conductive line is configured as a word line; wherein the pair of second conductive lines are configured as a pair of bit lines; and wherein the gate electrode is configured as a gate electrode of a first access transistor within a first DRAM cell and as a gate electrode of a second access transistor within a second DRAM cell.

3. The device of claim 2, wherein each of the first and second semiconductor patterns has a C-shape when viewed from a plan layout perspective; and wherein the gate insulating pattern has a circular ring shape when viewed from the plan layout perspective.

4. The device of claim 1, wherein the first conductive line is configured as a word line; wherein the pair of second conductive lines are configured as a pair of bit lines; and wherein the gate electrode is configured as a gate electrode of a first access transistor within a first DRAM cell and as a gate electrode of a second access transistor within a second DRAM cell.

5. The device of claim 4, wherein the first conductive line extends across a surface of the substrate in a first direction; wherein the pair of second conductive lines extend across the surface of the substrate in a second direction; and wherein the first direction is perpendicular to the second direction.

6. The device of claim 2, wherein the capacitor electrode of the first capacitor has a cylindrical shape and the capacitor electrode of the second capacitor has a cylindrical shape; wherein the gate electrode has a cylindrical shape; and wherein a longitudinal axis of the gate electrode is parallel to a longitudinal axis of the capacitor electrode of the first capacitor and parallel to a longitudinal axis of the capacitor electrode of the second capacitor.

7. The device of claim 3, further comprising a ferroelectric pattern extending between the first and second semiconductor patterns and the gate insulating pattern.

8. The device of claim 7, wherein the ferroelectric pattern has a circular ring shape when viewed from the plan layout perspective.

9. The device of claim 3, wherein the first semiconductor pattern comprises:
a first source/drain region, which is electrically connected to the first conductive pattern; and
a second source/drain region, which is electrically connected to the first one of the pair of second conductive lines.

10. The device of claim 9, wherein the first semiconductor pattern has a first surface thereon that contacts the first conductive pattern, and a second surface thereon that contacts the first one of the pair of second conductive lines.

11.-25. (canceled)

26. A semiconductor device, comprising:
a first conductive line provided on a substrate and extended in a first direction parallel to a top surface of the substrate;
a lower insulating layer on the first conductive line;
second conductive lines provided on the first conductive line and in the lower insulating layer and spaced apart from each other in the first direction;
a contact plug that penetrates the lower insulating layer between the second conductive lines and is connected to the first conductive line;
a gate electrode on the contact plug;
semiconductor patterns extending on the second conductive lines, respectively, and spaced apart from each other in the first direction; and
a gate insulating pattern extending between each of the semiconductor patterns and the gate electrode;
wherein a bottom surface of the gate insulating pattern is in contact with a top surface of the lower insulating layer.

27. The device of claim 26, wherein bottom surfaces of the semiconductor patterns are in contact with top surfaces of the second conductive lines, respectively.

28. The device of claim 27, wherein a bottom surface of the gate electrode is in contact with a top surface of the contact plug.

29. The device of claim 28, wherein the top surface of the lower insulating layer, the top surfaces of the second conductive lines, and the top surface of the contact plug are located at the same height from the top surface of the substrate in a direction perpendicular to the top surface of the substrate.

30. The device of claim 28, wherein each of the semiconductor patterns and the gate insulating pattern is a curved or bent pattern extends along a side surface of the gate electrode in a direction parallel to the top surface of the substrate.

31. A dual-DRAM cell, comprising:
a first access transistor of a first dynamic random access memory (DRAM) cell including a cylindrically-shaped gate electrode, which extends vertically relative to a surface of an underlying substrate; and
a second access transistor of a second DRAM cell that shares the cylindrically-shaped gate electrode.

32. The dual-DRAM cell of claim 31, wherein the first access transistor includes a first semiconductor active region that is C-shaped when viewed from a plan layout perspective; wherein the second access transistor includes a second semiconductor active region that is C-shaped when viewed from the plan layout perspective; and wherein the first and second semiconductor active regions are configured as mirror images of each other when viewed from the plan layout perspective.

33. The dual-DRAM cell of claim 32, further comprising:
a first bit line electrically connected to a source/drain region within the first semiconductor active region; and
a second bit line electrically connected to a source/drain region within the second semiconductor active region; and
wherein the cylindrically-shaped gate electrode extends between the first and second bit lines.

34. The dual-DRAM cell of claim 33, further comprising:
a word line, which extends between the first and second bit lines and the surface of the substrate and is electrically connected to the cylindrically-shaped gate electrode.

35. The dual-DRAM cell of claim 32, further comprising:
a first cylindrically-shaped capacitor electrode electrically connected to a source/drain region within the first semiconductor active region; and
a second cylindrically-shaped capacitor electrode electrically connected to a source/drain region within the second semiconductor active region.

36. (canceled)
